(19) United States
(12) Patent Application Publication
(10) Pub. No.: US 2015/0053937 A1
(43) Pub. Date: Feb. 26, 2015

(54) ORGANIC LIGHT-EMITTING DEVICE

(71) Applicant: SAMSUNG DISPLAY CO., LTD., Yongin-City (KR)

(72) Inventors: Jae-Hong KIM, Yongin-City (KR); Myeong-Suk KIM, Yongin-City (KR); Sung-Wook KIM, Yongin-City (KR); Jin-Soo HWANG, Yongin-City (KR)

(73) Assignee: SAMSUNG DISPLAY CO., LTD., Yongin-City (KR)

(21) Appl. No.: 14/242,032

(22) Filed: Apr. 1, 2014

(30) Foreign Application Priority Data
Aug. 23, 2013 (KR) 10-2013-0100565

(51) Int. Cl. H01L 51/00

(52) U.S. Cl. CPC H01L 51/006; H01L 51/0085; H01L 51/0061; H01L 51/5056
USPC 257/40

(57) ABSTRACT

An organic light-emitting device including a first electrode; a second electrode; and an organic layer between the first electrode and the second electrode, wherein the organic layer includes an emission layer and any one of a hole injection layer, a hole transport layer, or a functional layer having hole injection and hole transport abilities, wherein the emission layer includes an organic metal complex represented by Formula 1 herein, and wherein the hole injection layer, the hole transport layer, or the functional layer having hole injection and hole transport abilities includes a compound represented by Formula 2 or 3 herein.

### CROSS-REFERENCE TO RELATED APPLICATION

Korean Patent Application No. 10-2013-0100565, filed on Aug. 23, 2013, in the Korean Intellectual Property Office, and entitled: “Organic Light-Emitting Device,” is incorporated by reference herein in its entirety.

### BACKGROUND

1. Field

Embodiments relate to an organic light-emitting device.

2. Description of the Related Art

Organic light-emitting devices (OLEDs) are self-emitting devices having advantages such as wide viewing angles, good contrast, quick response times, high brightness, and good driving voltage. In addition, OLEDs may provide multicolored images.

### SUMMARY

Embodiments are directed to an organic light-emitting device.

According to one or more embodiments, an organic light-emitting device includes a first electrode, a second electrode, and an organic layer interposed between the first electrode and the second electrode, wherein the organic layer includes an emission layer and any one of a hole injection layer, a hole transport layer, and a functional layer having hole injection and hole transport abilities, wherein the EML includes an organic metal complex represented by Formula 1 below, and the HIL, the HTL, or the functional layer having hole injection and hole transport abilities includes a compound represented by Formula 2 or 3 below:

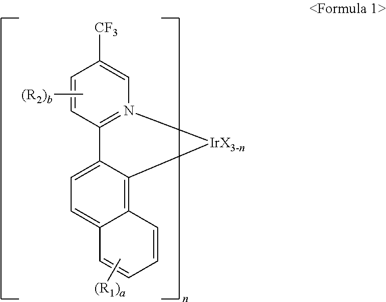

wherein R₁ and R₂ may be each independently selected from hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, and a substituted or unsubstituted C₂-C₆₀ heteroaryl group;
X may be a monovalent anion bidentate ligand;
a may be an integer of 1 to 3;
b may be an integer of 1 to 6, wherein, when b is 2 or more, optionally a plurality of R₂ groups are selectively linked to each other to form a ring;
n may be 2 or 3;

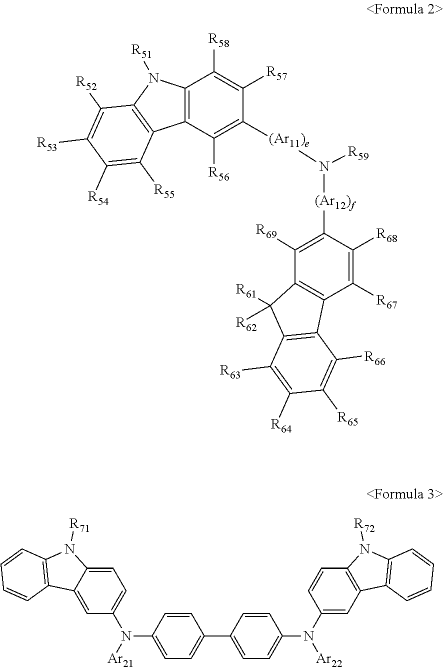

wherein Ar₁₁ and Ar₁₂ may be each independently a substituted or unsubstituted C₆-C₆₀ arylene group;
Ar₂₁ and Ar₂₂ may be each independently a substituted or unsubstituted C₆-C₆₀ aryl group;
e and f may be each independently an integer of 0 to 5;
R₅₁ through R₅₈, R₆₁ through R₆₉, R₇₁, and R₇₂ may be each independently hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group; and
R₅₉ may be a phenyl group; a naphthyl group; an anthryl group; a biphenyl group; a pyridyl group; or a phenyl group, a naphthyl group, an anthryl group, a biphenyl group, or a pyridyl group substituted with at least one of deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to one or more embodiments, a flat panel display device includes the organic light-emitting device, wherein a first electrode of the organic light-emitting diode is electrically connected to a source electrode or a drain electrode of a thin film transistor.

### BRIEF DESCRIPTION OF THE DRAWING

Features will be apparent to those of skill in the art by describing in detail exemplary embodiments with reference to the attached drawing in which:

FIG. 1 illustrates a schematic diagram of the structure of an organic light emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figure, the dimensions of layers and regions may be exaggerated for clarity of illustration.

As used herein, the term “and/or” includes any and all combinations of one or more of the associated listed items. Expressions such as “at least one of,” when preceding a list of elements, modify the entire list of elements and do not modify the individual elements of the list.

According to an embodiment, there is provided an organic light-emitting device including a first electrode, a second electrode, and an organic layer between the first electrode and the second electrode. The organic layer may include an emission layer (EML) and any one of a hole injection layer (HIL), a hole transport layer (HTL), or a functional layer having hole injection and hole transport abilities. The EML may include an organic metal complex represented by Formula 1 below, and the HIL, the HTL, or the functional layer having hole injection and hole transport abilities may include a compound represented by Formula 2 or 3, below.

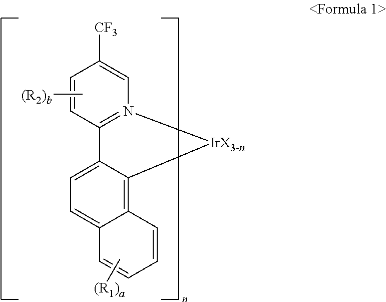

In Formula 1, R₁ and R₂ may be each independently selected from hydrogen, deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, and a substituted or unsubstituted C₂-C₆₀ heteroaryl group;
X may be a monovalent anion bidentate ligand;
a may be an integer of 1 to 3;
b may be an integer of 1 to 6, wherein, when b is 2 or more, optionally a plurality of R₂ groups are selectively linked to each other to form a ring; and
n may be 2 or 3.

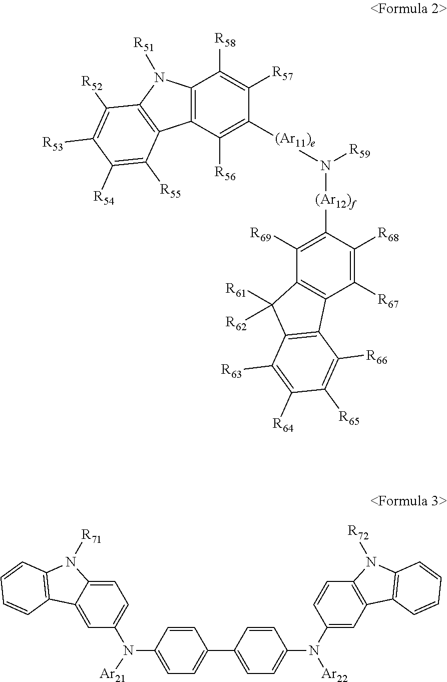

In Formulae 2 and 3, Ar₁₁ and Ar₁₂ may be each independently a substituted or unsubstituted C₆-C₆₀ arylene group;
Ar₂₁ and Ar₂₂ may be each independently a substituted or unsubstituted C₆-C₆₀ aryl group;
e and f may be each independently an integer of 0 to 5;
R₅₁ through R₅₈, R₆₁ through R₆₉, R₇₁, and R₇₂ may be each independently hydrogen, deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group; and
R₅₉ may be a phenyl group; a naphthyl group; an anthryl group; a biphenyl group; a pyridyl group; or a phenyl group, a naphthyl group, an anthryl group, a biphenyl group, or a pyridyl group substituted with at least one of deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

In Formula 1 above, a main ligand may be combined with or bound to the central metal Ir in a state of having steric hindrance with the central metal Ir to some extent due to a naphthyl group part (dotted circle region in the following formula) of the main ligand. Due to this, it may be understood that the compound (e.g., the complex represented by Formula 1) according to an embodiment may exhibit excellent properties, when compared to complexes that do not have such steric hindrance between the main ligand and the central metal Ir (See results of Comparative Examples 1 and 2, which will be described below). Such steric hindrance may have a positive effect on luminous properties, efficiency, and the like of the compound (e.g., the complex represented by Formula 1) according to an embodiment.

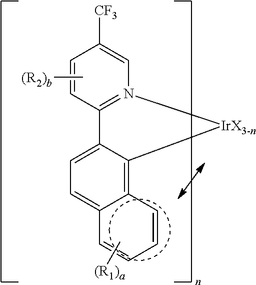

In the organic light-emitting device according to an embodiment, the EML may include the organic metal complex of Formula 1 and any one of the HIL, the HTL, and the functional layer having hole injection and hole transport abilities (which may include the compound of Formula 2 or 3). The organic light-emitting device may exhibit enhanced characteristics.

In an implementation, R₁ and R₂ may be each independently one of a C₆-C₁₄ aryl group; a C₂-C₁₄ heteroaryl group; and a C₆-C₁₄ aryl group and a C₂-C₁₄ heteroaryl group that are substituted with at least one of deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, and a C₁-C₂₀ alkoxy group, a C₆-C₁₄ aryl group, and a C₂-C₁₄ heteroaryl group.

In an implementation, R₁ and R₂ may be each independently one of a phenyl group; a biphenyl group; a naphthyl group; an anthryl group; pyrenyl group; a phenanthrenyl group; a fluorenyl group; a pyridinyl group; a pyrazinyl group; a pyrimidinyl group; a triazinyl group; a quinolinyl group; an isoquinolinyl group; a quinoxalinyl group; a phenanthrolinyl group; a carbazolyl group; and a phenyl group, a biphenyl group, a naphthyl group, an anthryl group, a pyrenyl group, a phenanthrenyl group, a fluorenyl group, a pyridinyl group, a bipyridinyl group, a terpyridinyl group, a pyrazinyl group, a pyrimidinyl group, a triazinyl group, a quinolinyl group, an isoquinolinyl group, a quinoxalinyl group, a phenanthrolinyl group, and a carbazolyl group that are substituted with at least one of deuterium, F, Cl, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazolyl group.

According to another embodiment, R₁ and R₂ may be each independently hydrogen, deuterium, —CF₃, or a group represented by Formula 2a below.

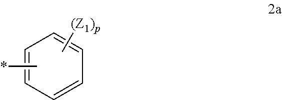

In Formula 2a, Z₁ may be a hydrogen atom, deuterium, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, an amino group substituted with a C₆-C₂₀ aryl group or a C₂-C₂₀ heteroaryl group, a halogen group, a cyano group, a nitro group, a hydroxyl group, or a carboxyl group; p may be an integer of 1 to 5; and * denotes a binding site.

In another embodiment, the complex represented by Formula 1 above may be represented by Formula 1-1 below:

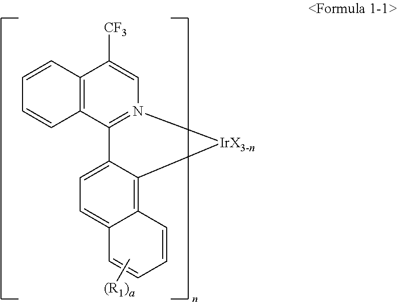

The complex represented by Formula 1-1 above is an example in which a plurality of R₂ groups of Formula 1 is linked to each other to form a ring, and definition of other substituents and symbols of Formula 1-1 have already been described.

In another embodiment, X may be aetylacetonate, hexafluoroacetonate, tetramethylheptadionate, dibenzoylmethane, picolinate, salicylanilide, 8-hydroxyquinolate, or 1,5-dimethyl-3-pyrazole carboxylate.

In another embodiment, X may be represented by Formula 3a or 3b below:

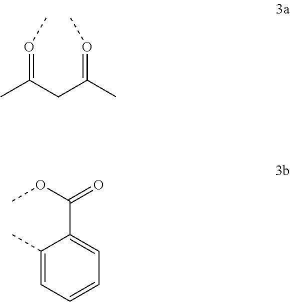

In Formulae 3a and 3b, above, dotted lines denote binding sites or locations with Ir.

For example, the organic metal complex represented by Formula 1, e.g., an Ir complex, may be one of the following compounds.

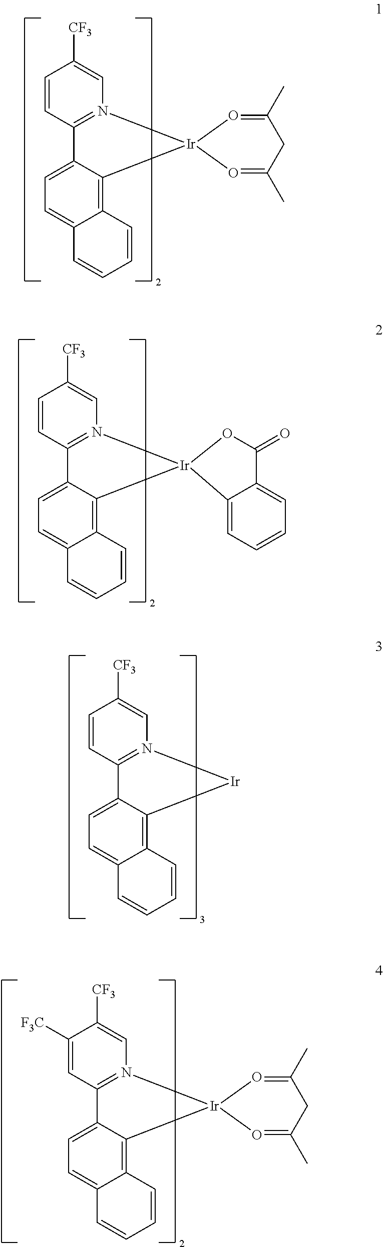

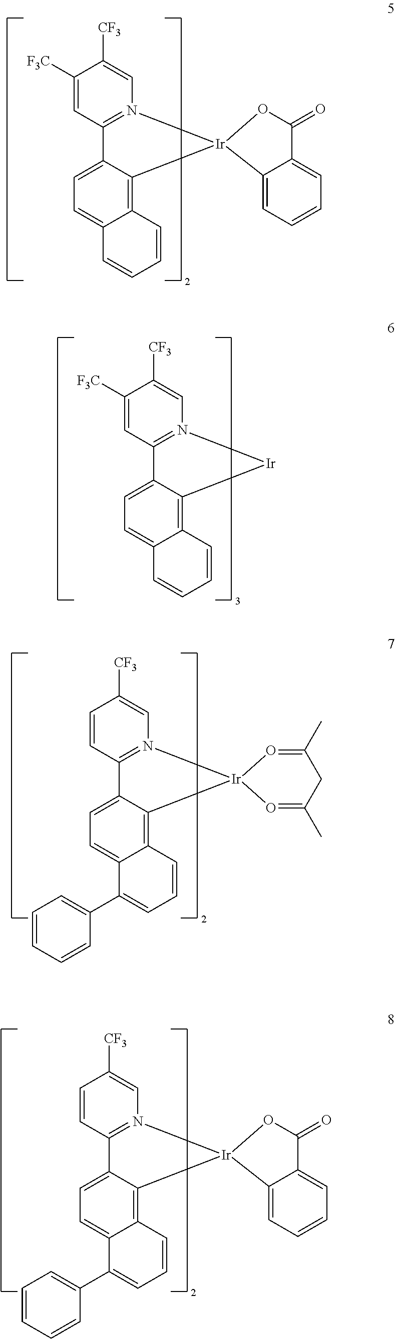

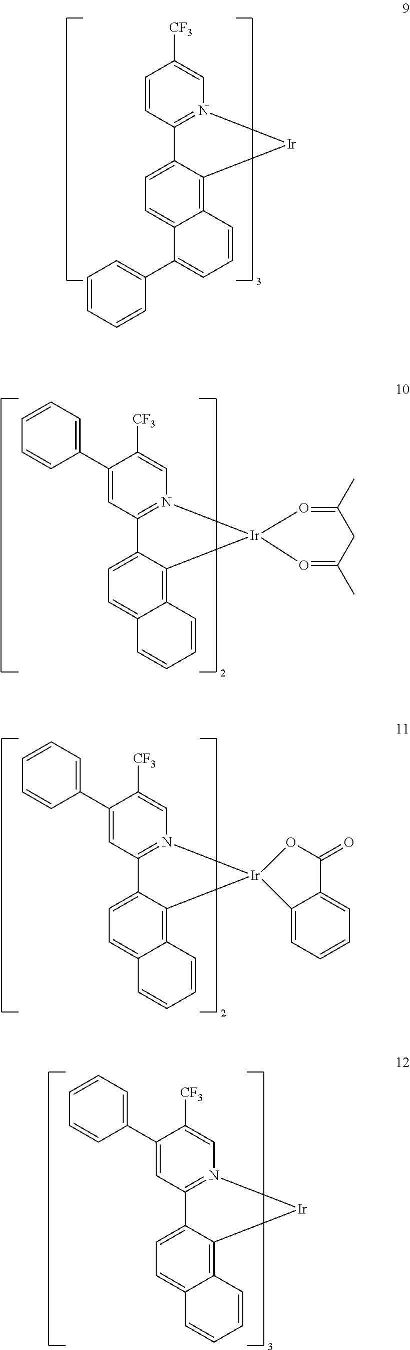

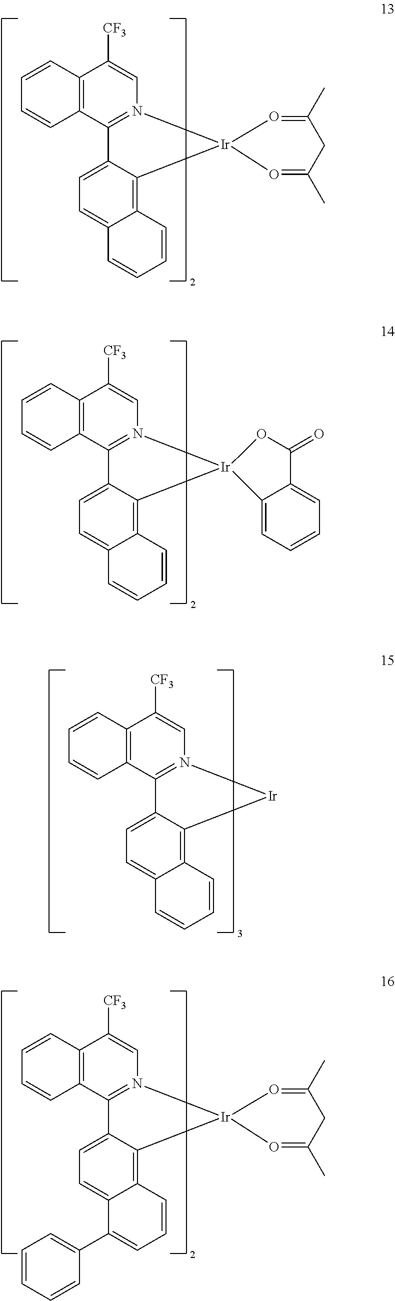

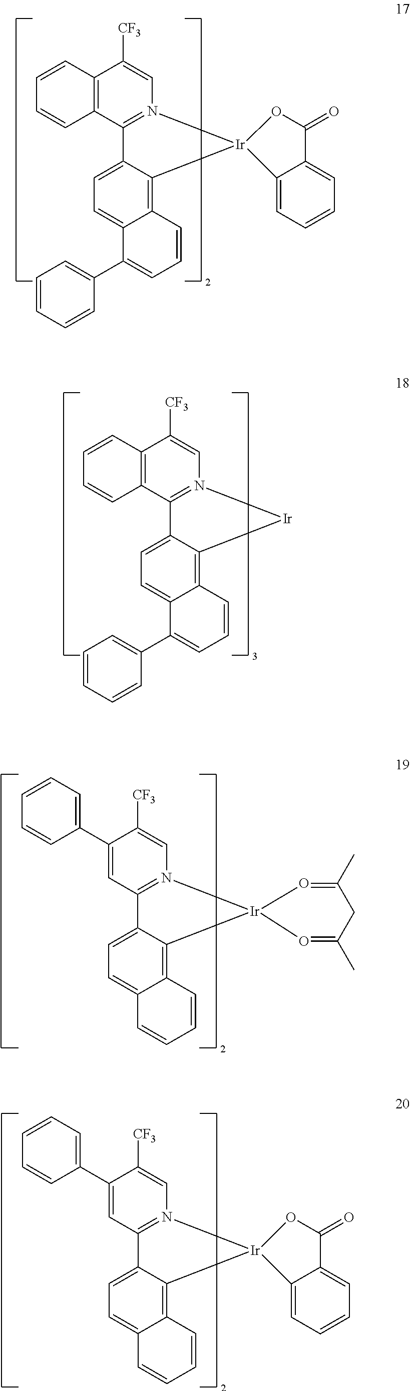

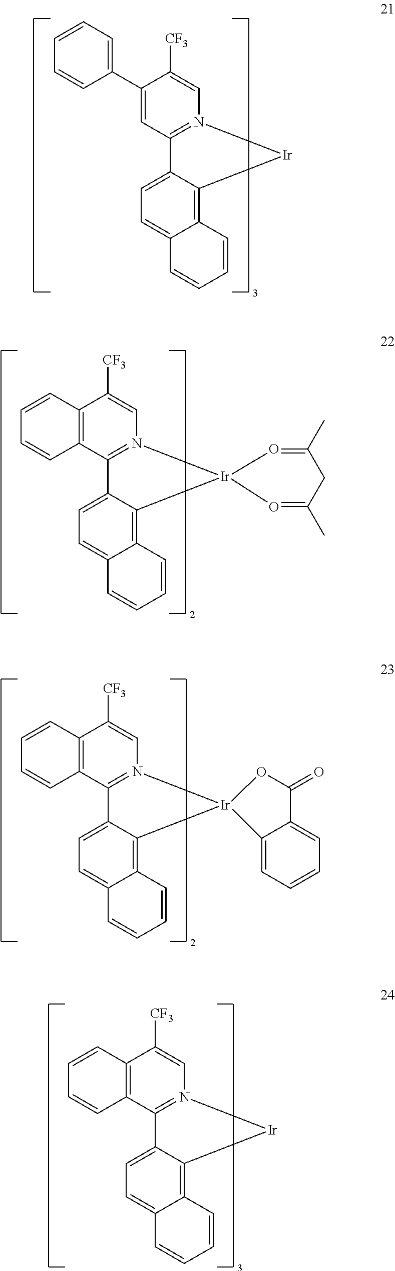

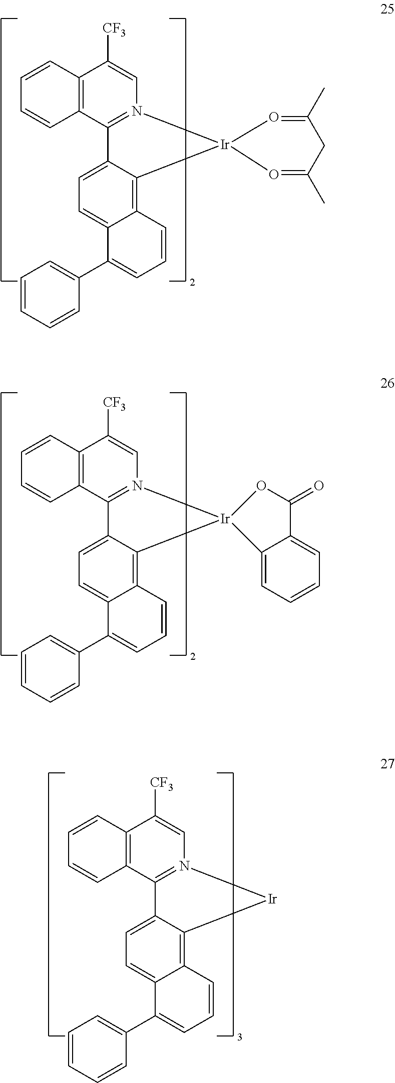

Hereinafter, representative groups of the substituents as used herein will be described (The number of carbon atoms that define the substituents is non-limiting and do not limit the properties of the substituents, and substituents that are not described here are in accordance with general definition).

The unsubstituted C₁-C₆₀ alkyl group is a linear or branched alkyl group. Examples of the unsubstituted C₁-C₆₀ alkyl group include methyl, ethyl, propyl, isobutyl, sec-butyl, pentyl, iso-amyl, hexyl, heptyl, octyl, nonanyl, dodecyl, and the like. At least one hydrogen atom of the unsubstituted C₁-C₆₀ alkyl group may be substituted with deuterium, a halogen atom, a hydroxyl group, a nitro group, a cyano group, an amino group, an amidino group, hydrazine, hydrazone, a carboxyl group or a salt thereof, a sulfonic acid group or a salt thereof, a phosphoric acid or a salt thereof, a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₂-C₁₆ heteroaryl group.

The unsubstituted C₂-C₆₀ alkenyl group is a group containing at least one carbon-carbon double bond in the center or at a terminal end of the unsubstituted C₁-C₆₀ alkyl group. Examples of the unsubstituted C₂-C₆₀ alkenyl group include ethenyl, propenyl, butenyl, and the like. At least one hydrogen atom of the unsubstituted C₂-C₆₀ alkenyl group may be substituted with the substituents described above with respect to the substituted C₁-C₆₀ alkyl group.

The unsubstituted C₂-C₆₀ alkynyl group is a group containing at least one carbon-carbon triple bond in the center or at a terminal end of the C₁-C₆₀ alkyl group defined above. Examples of the unsubstituted C₂-C₆₀ alkynyl group include acetylene, propylene, phenylacetylene, naphthylacetylene, isopropylacetylene, t-butylacetylene, diphenylacetylene, and the like. At least one hydrogen atom of the unsubstituted C₂-C₆₀ alkynyl group may be substituted with the substituents described above with respect to the substituted C₁-C₆₀ alkyl group.

The unsubstituted C₃-C₆₀ cycloalkyl group denotes a C₃-C₆₀ ring-type alkyl group. At least one hydrogen atom of the unsubstituted C₃-C₆₀ cycloalkyl group may be substituted with the substituents described above with respect to the substituted C₁-C₆₀ alkyl group.

The unsubstituted C₁-C₆₀ alkoxy group has the Formula —OA in which A is the unsubstituted C₁-C₆₀ alkyl group. Non-limiting examples of the unsubstituted C₁-C₆₀ alkoxy group include methoxy, ethoxy, propoxy, isopropyloxy, butoxy, pentoxy, and the like. At least one hydrogen atom of the unsubstituted C₁-C₆₀ alkoxy group may be substituted with the substituents described above with respect to the substituted C₁-C₆₀ alkyl group.

The unsubstituted C₆-C₆₀ aryl group refers to a C₆-C₆₀ carbocyclic aromatic system containing at least one ring, wherein when it contains at least two rings, the rings may be fused with each other or linked to each other by a single bond. The term “aryl” refers to an aromatic system, including phenyl, naphthyl, anthracenyl, and the like. At least one hydrogen atom of the unsubstituted C₆-C₆₀ aryl group may be substituted with the substituents described above with respect to the substituted C₁-C₆₀ alkyl group.

Examples of the substituted or unsubstituted C₆-C₆₀ aryl group include a phenyl group, a C₁-C₁₀ alkylphenyl group (e.g., an ethylphenyl group), a biphenyl group, a C₁-C₁₀ alkylbiphenyl group, a C₁-C₁₀ alkoxybiphenyl group an o-, m-, and p-tolyl group, an o-, m- and p-cumenyl group, a mesityl group, a phenoxyphenyl group, an (α,α-dimethylbenzene)phenyl group, a (N,N′-dimethyl)aminophenyl group, a (N,N′-diphenyl)aminophenyl group, a pentalenyl group, an indenyl group, a naphthyl group, a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylene group, a pyrenyl group, a chrysenyl group, an ethyl-chrysenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl, a pyranthrenyl group, and an ovalenyl group.

The unsubstituted C₂-C₆₀ heteroaryl group indicates a group having 1, 2, 3 or 4 hetero atom(s) selected from N, O, P, and S. When the C₂-C₆₀ heteroaryl group contains at least two rings, the rings may be fused with each other or linked to each other by a single bond. Non-limiting examples of the unsubstituted C₂-C₆₀ heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, and a dibenzothiophene group. At least one hydrogen atom of the unsubstituted C₂-C₆₀ heteroaryl group may be substituted with the substituents described above with respect to the substituted C₁-C₆₀ alkyl group.

The unsubstituted C₆-C₆₀ aryloxy group has the formula —OA₁ in which A₁ is the C₆-C₆₀ aryl group as described above. Non-limiting examples of the unsubstituted C₆-C₆₀ aryloxy group include a phenoxy group and the like. At least one hydrogen atom of the unsubstituted C₆-C₆₀ aryloxy group may be substituted with the substituents described above with respect to the substituted C₁-C₆₀ alkyl group.

The unsubstituted C₆-C₆₀ arylthio group has the formula —SA₁ in which A₁ is the C₆-C₆₀ aryl group described above. Non-limiting examples of the unsubstituted C₆-C₆₀ arylthio group may include a benzenethio group, a naphthylthio group, and the like. At least one hydrogen atom of the unsubstituted C₆-C₆₀ arylthio group may be substituted with the substituents described above with respect to the substituted C₁-C₆₀ alkyl group.

The unsubstituted C₆-C₆₀ condensed polycyclic group indicates a substituent having at least two rings in which at least one aromatic ring and/or at least one non-aromatic ring are fused with each other, or a substituent having an unsaturated group but not having a conjugated system in the ring. The unsubstituted C₆-C₆₀ condensed polycyclic group differs from the aryl and heteroaryl groups in that it is overall non-aromatic.

The expression “(an organic layer) includes at least one iridium complex” as used herein may be interpreted such that the organic layer may include one of the iridium complexes of Formula 1 or at least two (e.g., complexes 1 and 2) of the iridium complexes of Formula 1.

For example, the organic layer may include only the complex 1 as the iridium complex. In this regard, the complex 1 may be included in the EML of the organic light-emitting device. In another embodiment, the organic layer may include the complexes 1 and 2 as the iridium complex. In this regard, the complexes 1 and 2 may be included in the same layer (e.g., the EML).

The organic layer may further include, between the first electrode and the EML, at least one of a HIL, a HTL, a functional layer having hole injection and hole transport abilities (hereinafter referred to as an “H-functional layer”), a buffer layer, and/or an electron blocking layer (EBL). In addition, the organic layer may further include, between the EML and the second electrode, at least one of a hole blocking layer (HBL), an electron transport layer (ETL), an electron injection layer (EIL), and/or a functional layer having electron injection and electron transport abilities.

The term “organic layer” as used herein refers to a single layer and/or a plurality of layers disposed between the first electrode and the second electrode.

The organic layer may include an EML including at least one of the iridium complexes.

The iridium complex included in the EML may be a phosphorescent dopant, and the EML may further include a host. Types of the host will be described below.

The above-described organic light-emitting device including the iridium complex may emit red light, e.g., red phosphorescent light.

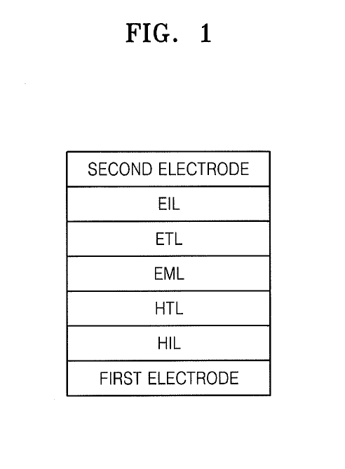

FIG. 1 illustrates a schematic diagram of the structure of an OLED according to an embodiment. Hereinafter, a structure and manufacturing method of an OLED will be described in more detail with reference to FIG. 1.

A substrate (not shown) may be a suitable substrate used in OLEDs, and may be, e.g., a glass substrate or a transparent plastic substrate having good mechanical strength, thermal stability, transparency, surface smoothness, ease of handling, and waterproofness.

The first electrode may be formed by applying a first electrode material on the substrate by deposition or sputtering. When the first electrode is an anode, the first electrode material may be selected from materials having a high work function so as to facilitate hole injection. The first electrode may be a reflective electrode or a transparent electrode. Examples of the first electrode material may include indium-tin oxide (ITO), indium-zinc-oxide (IZO), tin oxide (SnO₂), and zinc oxide (ZnO) which are transparent and have high conductivity. In another embodiment, when magnesium (Mg), aluminum (Al), aluminum-lithium (Al—Li), calcium (Ca), magnesium-indium (Mg—In), or magnesium-silver (Mg—Ag) is used as the first electrode material, the first electrode may be formed as a reflective electrode.

The first electrode may be formed as a single layer or have a multi-layered structure with at least two layers. For example, the first electrode may have a three-layered structure including ITO/Ag/ITO.

The organic layer may be formed on the first electrode.

The organic layer may include a HIL, a HTL, a functional layer having hole injection and hole transport abilities, a buffer layer, an EML, an ETL, an EIL, or a functional layer having electron injection and electron transport abilities.

The HIL may be formed on the first electrode by using various methods, e.g., vacuum deposition, spin coating, casting, or LB deposition.

When the HIL is formed by vacuum deposition, the deposition conditions may vary according to the compound used as the material for forming the HIL, the structure of the desired HIL, and the thermal characteristics. For example, the deposition conditions may be a deposition temperature of about 100° C. to about 500° C., a degree of vacuum of about 10⁻⁸ torr to about 10⁻³ torr, and a deposition speed of about 0.01 Å/sec to about 100 Å/sec.

When the HIL is formed by spin coating, the coating conditions may vary according to the compound used as the material for forming the HIL, the structure of the desired HIL, and the thermal characteristics. For example, the coating conditions may be a coating speed of about 2,000 rpm to about 5,000 rpm and a heat treatment temperature for removing the solvent after coating of about 80° C. to about 200° C.

The material for forming the HIL may include a suitable hole injection material. Examples of the hole injection material may include N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate (PEDOT/PSS), polyaniline/camphor sulfonicacid (Pani/CSA), and (polyaniline)/poly(4-styrenesulfonate) (PANI/PSS):

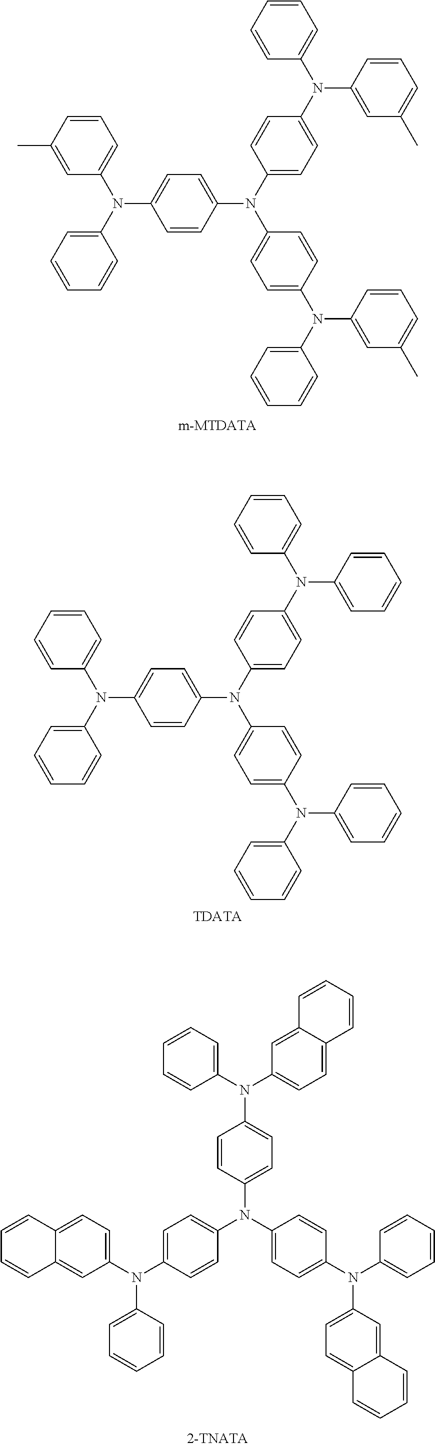

The thickness of the HIL may be about 100 Å to about 10,000 Å. In some embodiments, the thickness of the HIL may be about 100 Å to about 1,000 Å. When the thickness of the HIL is within these ranges, satisfactory hole injection properties may be obtained without a substantial increase in driving voltage.

Next, the HTL may be formed on the HIL by various methods, such as vacuum deposition, spin coating, casting, or LB deposition. When the HTL is formed by vacuum deposition or spin coating, the deposition or coating conditions may vary according to the compounds used. However, in an implementation, the deposition or coating conditions may be similar or identical to the conditions used for forming the HIL.

A material for forming the HTL may include a suitable hole transporting material. Examples of the hole transporting material may include carbazole derivatives such as N-phenylcarbazole and polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine (NPB).

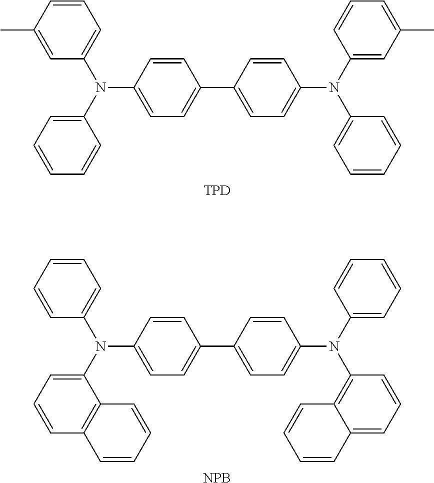

The thickness of the HTL may be about 50 Å to about 2,000 Å. In some embodiments, the thickness of the HTL may be about 100 Å to about 1,500 Å. When the thickness of the HTL is within these ranges, satisfactory hole transport properties may be obtained without a substantial increase in driving voltage.

The H-functional layer may include at least one of the hole injection materials and the hole transporting materials described above. The thickness of the H-functional layer may be about 500 Å to about 10,000 Å. In some embodiments, the thickness of the H-functional layer may be about 100 Å to about 1,000 Å. When the thickness of the H-functional layer is within these ranges, satisfactory hole injection and hole transport properties may be obtained without a substantial increase in driving voltage.

At least one of the HIL, the HTL, and the H-functional layer may include at least one of a compound represented by Formula 2 below or a compound represented by Formula 3 below:

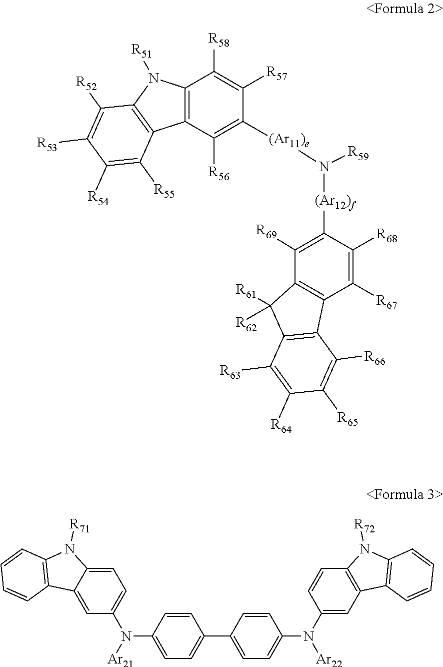

In Formula 2, Ar₁₁ and Ar₁₂ may be each independently a substituted or unsubstituted C₆-C₆₀ arylene group. For example, Ar₁₁ and Ar₁₂ may be each independently a substituted or unsubstituted phenylene group, a substituted or unsubstituted naphthylene group, a substituted or unsubstituted fluorenylene group, or a substituted or unsubstituted anthrylene group. In an implementation, at least one substituent of the substituted phenylene group, the substituted naphthylene group, the substituted fluorenylene group, and the substituted anthrylene group may be deuterium, a halogen atom, a hydroxyl group, a cyano group, a C₁-C₂₀ alkyl group, a C₁-C₂₀ alkoxy group, a phenyl group, a naphthyl group, an anthryl group, a carbazolyl group, a phenyl-substituted carbazolyl group.

In Formula 3, Ar₂₁ and Ar₂₂ may be each independently a substituted or unsubstituted C₆-C₆₀ aryl group or a substituted or unsubstituted C₂-C₆₀ heteroaryl group. For example, Ar₂₁ and Ar₂₂ may be each independently a substituted or unsubstituted phenyl group, a substituted or unsubstituted naphthyl group, a substituted or unsubstituted phenanthrenyl group, a substituted or unsubstituted anthryl group, a substituted or unsubstituted pyrenyl group, a substituted or unsubstituted chrysenyl group, a substituted or unsubstituted fluorenyl group, a substituted or unsubstituted carbazolyl group, a substituted or unsubstituted dibenzofuranyl group, or a substituted or unsubstituted dibenzothiophenyl group. In an implementation, at least one substituent of the substituted phenyl group, the substituted naphthyl group, the substituted phenanthrenyl group, the substituted anthryl group, the substituted pyrenyl group, the substituted chrysenyl group, the substituted fluorenyl group, the substituted carbazolyl group, the substituted dibenzofuranyl group, and the substituted dibenzothiophenyl group may be selected from deuterium; a halogen atom; a hydroxyl group; a cyano group; a nitro group; an amino group; an amidino group; a hydrazine group; a hydrazone group; a carboxyl group or a salt thereof; a sulfonic acid group or a salt thereof; a phosphoric acid or a salt thereof; a C₁-C₁₀ alkyl group; a C₁-C₁₀ alkoxy group; a phenyl group; a naphthyl group; a fluorenyl group; a phenanthrenyl group; an anthryl group; a triphenylenyl group; a pyrenyl group; a chrysenyl group; an imidazolyl group; an imidazolinyl group; an imidazopyridinyl group; an imidazopyrimidinyl group; a pyridinyl group; a pyrazinyl group; a pyrimidinyl group; an indolyl group; and a phenyl group, a naphthyl group, a fluorenyl group, a phenanthrenyl group, an anthryl group, a triphenylenyl group, a pyrenyl group, a chrysenyl group, an imidazolyl group, an imidazolinyl group, an imidazopyridinyl group, an imidazopyrimidinyl group, a pyridinyl group, a pyrazinyl group, a pyrimidinyl group, and an indolyl group that are substituted with at least one of deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid or a salt thereof, a C₁-C₁₀ alkyl group, and a C₁-C₁₀ alkoxy group.

In Formula 2, e and f may be each independently an integer of 0 to 5, e.g., 0, 1, or 2. For example, e may be 1 and f may be 0.

In Formulae 2 and 3, R₅₁ through R₅₈, R₆₁ through R₆₉, R₇₁, and R₇₂ may be each independently hydrogen, deuterium, a halogen atom, a hydroxyl group, a cyano group, —NO₂, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group.

For example, R₅₁ through R₅₈, R₆₁ through R₆₉, R₇₁, and R₇₂ may be each independently one of hydrogen; deuterium; a halogen atom; a hydroxyl group; a cyano group; —NO₂; an amino group; an amidino group; a hydrazine group; a hydrazone group; a carboxyl group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, a hexyl group, and the like); a C₁-C₁₀ alkoxy group (for example, a methoxy group, an ethoxy group, a propoxy group, a butoxy group, a pentoxy group, and the like); a C₁-C₁° alkyl group and a C₁-C₁₀ alkoxy group that are substituted with at least one of deuterium, a halogen atom, a hydroxyl group, a cyano group, —NO₂, an amino group, an amidino group, hydrazine, hydrazone, a carboxyl group or a salt thereof, a sulfonic acid group or a salt thereof, and a phosphoric acid or a salt thereof; a phenyl group; a naphthyl group; an anthryl group; a fluorenyl group; a pyrenyl group; and a phenyl group, a naphthyl group, an anthryl group, a fluorenyl group, and a pyrenyl group that are substituted with at least one of deuterium, a halogen atom, a hydroxyl group, a cyano group, —NO₂, an amino group, an amidino group, a hydrazine group, a hydrazone group, a carboxyl group or a salt thereof, a sulfonic acid group or a salt thereof, a phosphoric acid group or a salt thereof, a C₁-C₁₀ alkyl group, and a C₁-C₁₀ alkoxy group.

In Formula 2, R₅₉ may be one of a phenyl group; a naphthyl group; an anthryl group; a biphenyl group; a pyridyl group; and a phenyl group, a naphthyl group, an anthryl group, a biphenyl group and a pyridyl group that are substituted with at least one of deuterium, a halogen atom, a hydroxyl group, a cyano group, —NO₂, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₂₀ alkyl group, and a substituted or unsubstituted C₁-C₂₀ alkoxy group.

In an implementation, the compound of Formula 2 may be a compound represented by Formula 4 below.

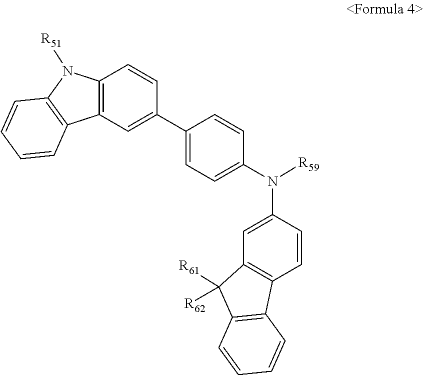

In Formula 4, R₅₁, R₆₁, R₆₂, and R₅₉ may be the same as defined above with respect to Formula 2.

In an implementation, at least one of the HIL, the HTL, and the H-functional layer may include at least one of Compounds 301 through 320 below.

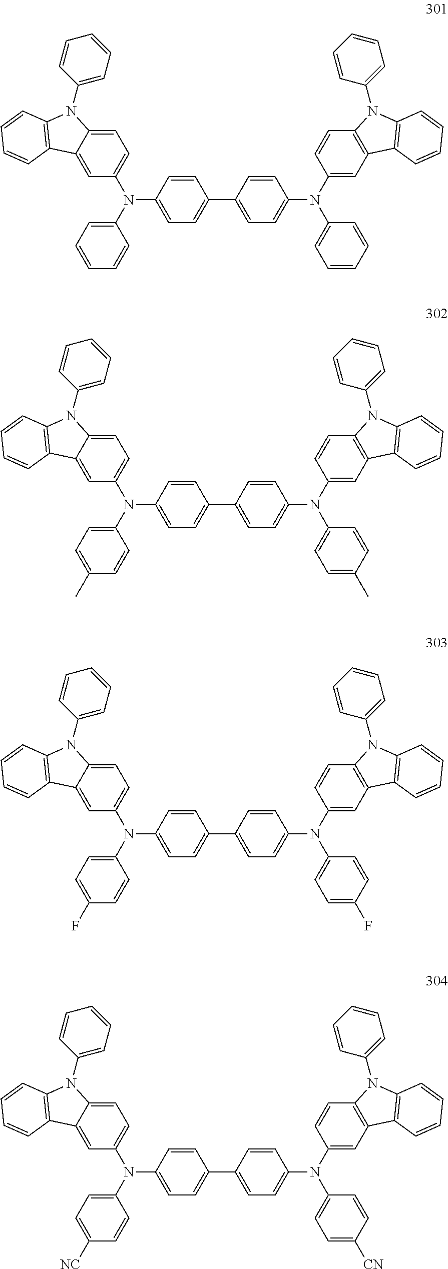 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

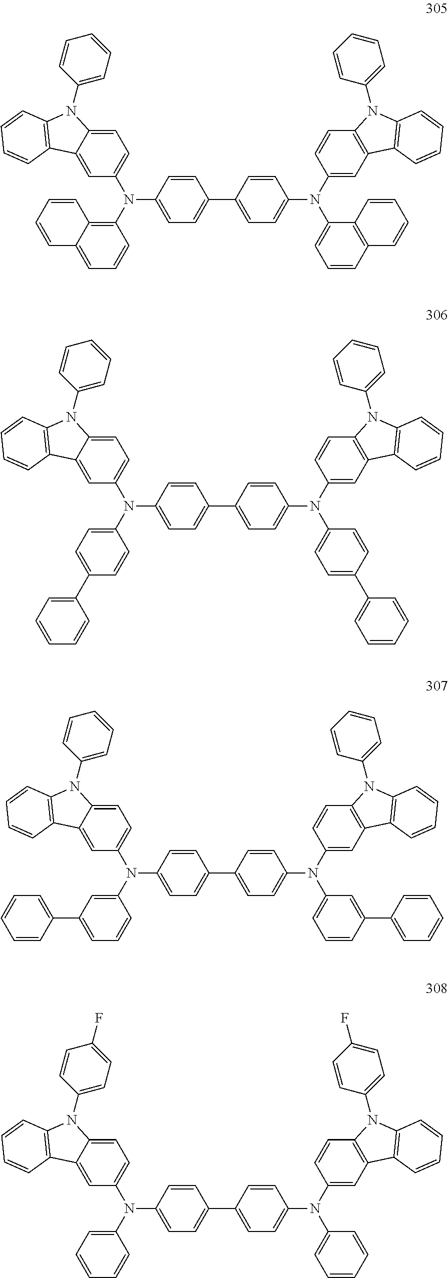 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

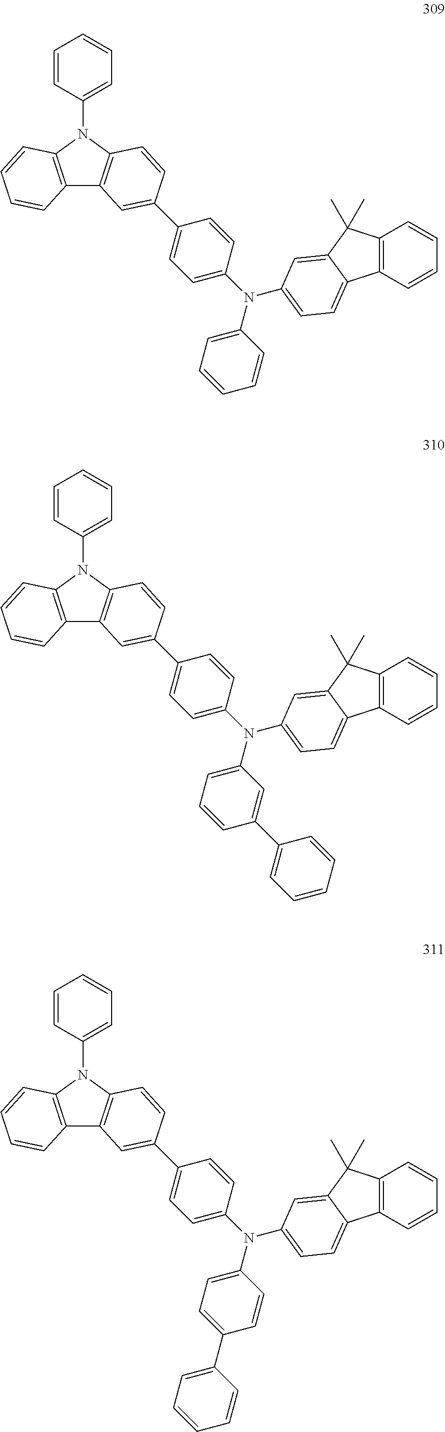 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

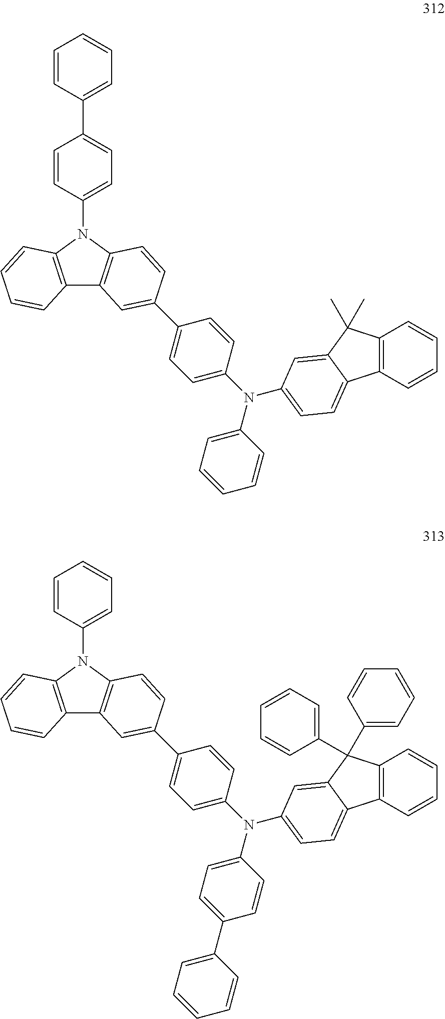 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

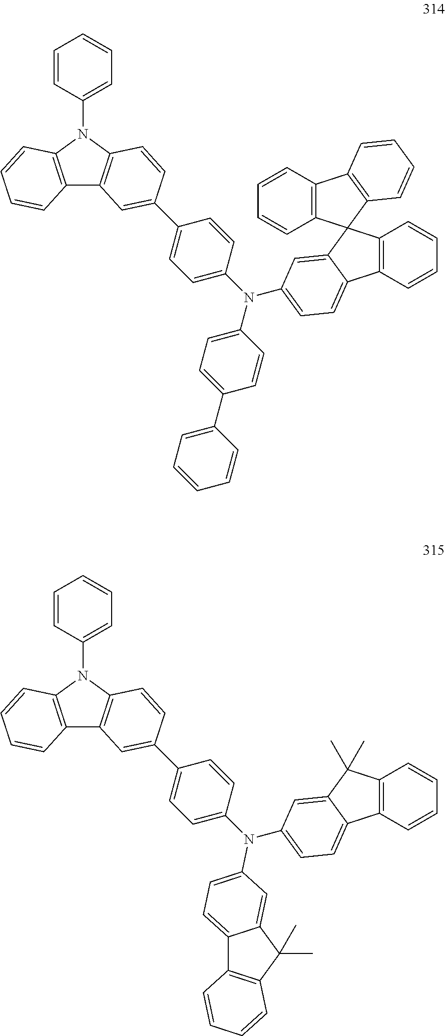 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

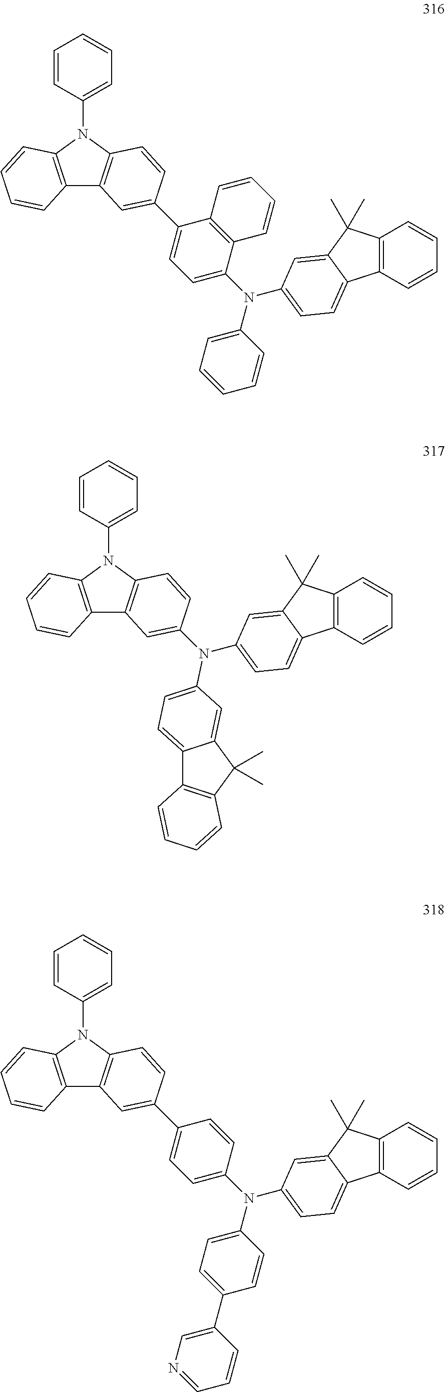 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

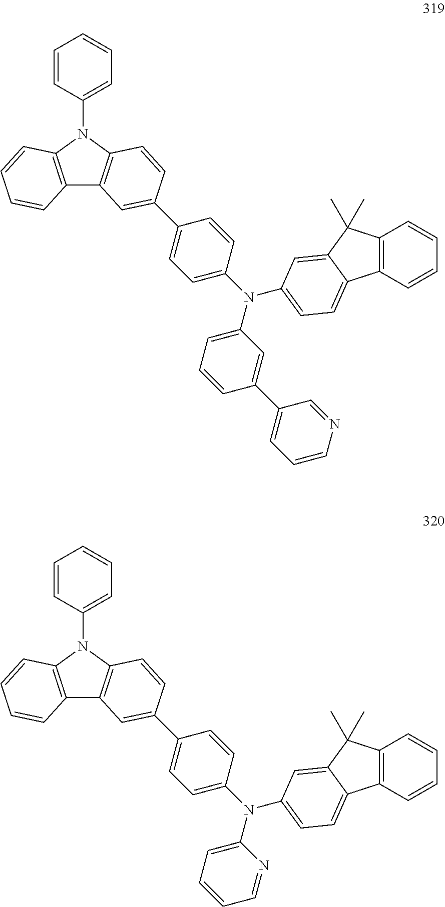 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, the HTL, and the H-functional layer may further include a charge-generating material so as to increase the conductivity of the layers, in addition to the suitable hole injection material, the suitable hole transporting material, and/or material having hole injection and hole transport abilities.

The charge-generating material may be, e.g., a p-dopant. The p-dopant may include one of quinone derivatives, metal oxides, and cyano-containing compounds. Examples of the p-dopant may include quinone derivatives such as tetra-cyanoquinodimethane (TCNQ) and 2,3,5,6-tetrafluoro-tetracyano-1,4-benzoquinodimethane (F4-TCNQ); metal oxides such as an tungsten oxide and molybdenum oxide; and cyano-containing compounds such as Compound 200 below and the like.

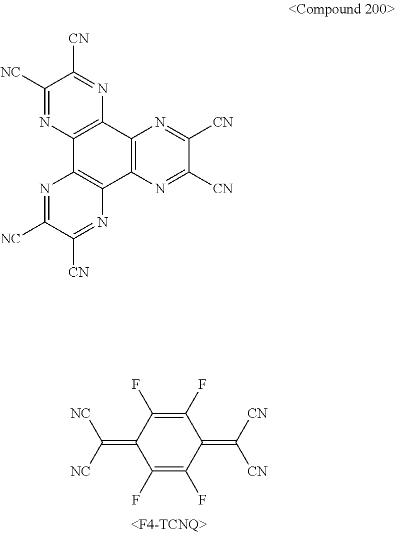 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the HIL, the HTL or the H-functional layer further includes the charge-generating material, the charge-generating material may be homogeneously or heterogeneously dispersed in these layers.

The buffer layer may be between the EML and at least one of the HIL, the HTL, and the H-functional layer. The buffer layer may help increase efficiency by compensating for an optical resonance distance according to the wavelength of light emitted from the EML. The buffer layer may include a suitable hole injection material and/or a suitable hole transporting material. In an implementation, the buffer layer may include the same material as one of the materials included in the HIL, the HTL, and the H-functional layer which are formed below the buffer layer.

Next, the EML may be formed on the HTL, the H-functional layer, or the buffer layer by vacuum deposition, spin coating, casting, or LB deposition. When the EML is formed by vacuum deposition or spin coating, the deposition or coating conditions may vary according to the compounds used. However, in general, the conditions may be similar or identical to the conditions for forming the HIL.

The EML may include at least one of the iridium complexes according to an embodiment.

The iridium complex included in the EML may serve as a dopant (e.g., a red phosphorescent dopant). In this regard, the EML may further include a host, in addition to the iridium complex.

Examples of the host may include Alq₃, 4,4′-N,N′-dicabazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di(naphth-2-yl) anthracene (TBADN), mCP, and OXD-7.

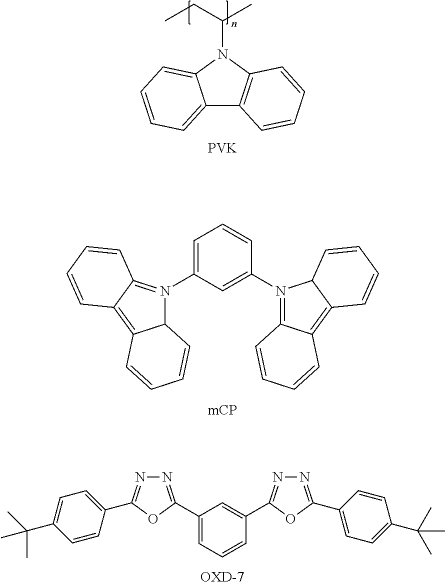

In another embodiment, a carbazole-based compound represented by Formula 10 below may be used as the host:

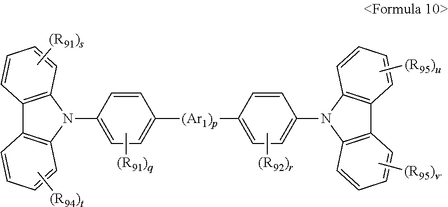

In Formula 10, Ar₁ may be a substituted or unsubstituted C₁-C₆₀ alkylene group, a substituted or unsubstituted C₂-C₆₀ alkenylene group, —C(═O)—, —N(R₁₀₀)— (in which R₁₀₀ is a substituted or unsubstituted C₆-C₆₀ aryl group or a substituted or unsubstituted C₂-C₆₀ heteroaryl group), a substituted or unsubstituted C₆-C₆₀ arylene group, or a substituted or unsubstituted C₂-C₆₀ heteroarylene group; p may be an integer of 0 to 10; R₉₁ through R₉₆ may be each independently hydrogen, deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, or a substituted or unsubstituted C₂-C₆₀ heteroaryl group, in which two adjacent substituents of R₉₁ through R₉₆ may be selectively linked to each other to form a substituted or unsubstituted C₄-C₂₀ alicyclic ring, a substituted or unsubstituted C₂-C₂₀ hetero alicyclic ring, a substituted or unsubstituted C₆-C₂₀ aromatic ring, or a substituted or unsubstituted C₂-C₂₀ heteroaromatic ring; and q, r, s, t, u, and v may be each independently an integer of 1 to 4.

In Formula 10, Ar₁ may be a C₁-C₅ alkylene group, a C₂-C₅ alkenylene group, —C(═O)—, or —N(R₁₀₀)—. In this regard, R₁₀₀ may be one of a phenyl group; a naphthyl group; an anthryl group; a fluorenyl group; a carbazolyl group; a pyridinyl group, a pyrimidinyl group; a triazinyl group; and a phenyl group, a naphthyl group, an anthryl group, a fluorenyl group, a carbazolyl group, a pyridinyl group, a pyrimidinyl group, and a triazinyl group that are substituted with at least one of deuterium, a halogen atom, a hydroxyl group, a cyano group, a nitro group, an amino group, a C₁-C₂₀ alkyl group, a C₁-C₂₀ alkoxy group, a phenyl group, a naphthyl group, an anthryl group, a fluorenyl group, a carbazolyl group, a pyridinyl group, a pyrimidinyl group, and a triazinyl group.

In Formula 10, R₉₁ through R₉₆ may be each independently one of hydrogen; deuterium; a halogen atom; a hydroxyl group; a cyano group; a nitro group; an amino group; an amidino group; a hydrazine group; a hydrazone group; a carboxyl group or a salt thereof; a sulfonic acid group or a salt thereof; a phosphoric acid or a salt thereof; a C₁-C₂₀ alkyl group; a C₁-C₂₀ alkoxy group; and a C₁-C₂₀ alkyl group and a C₁-C₂₀ alkoxy group that are substituted with at least one of deuterium, a halogen atom, a hydroxyl group, a cyano group, a nitro group, and an amino group.

The carbazole-based compound may be one of the following compounds.

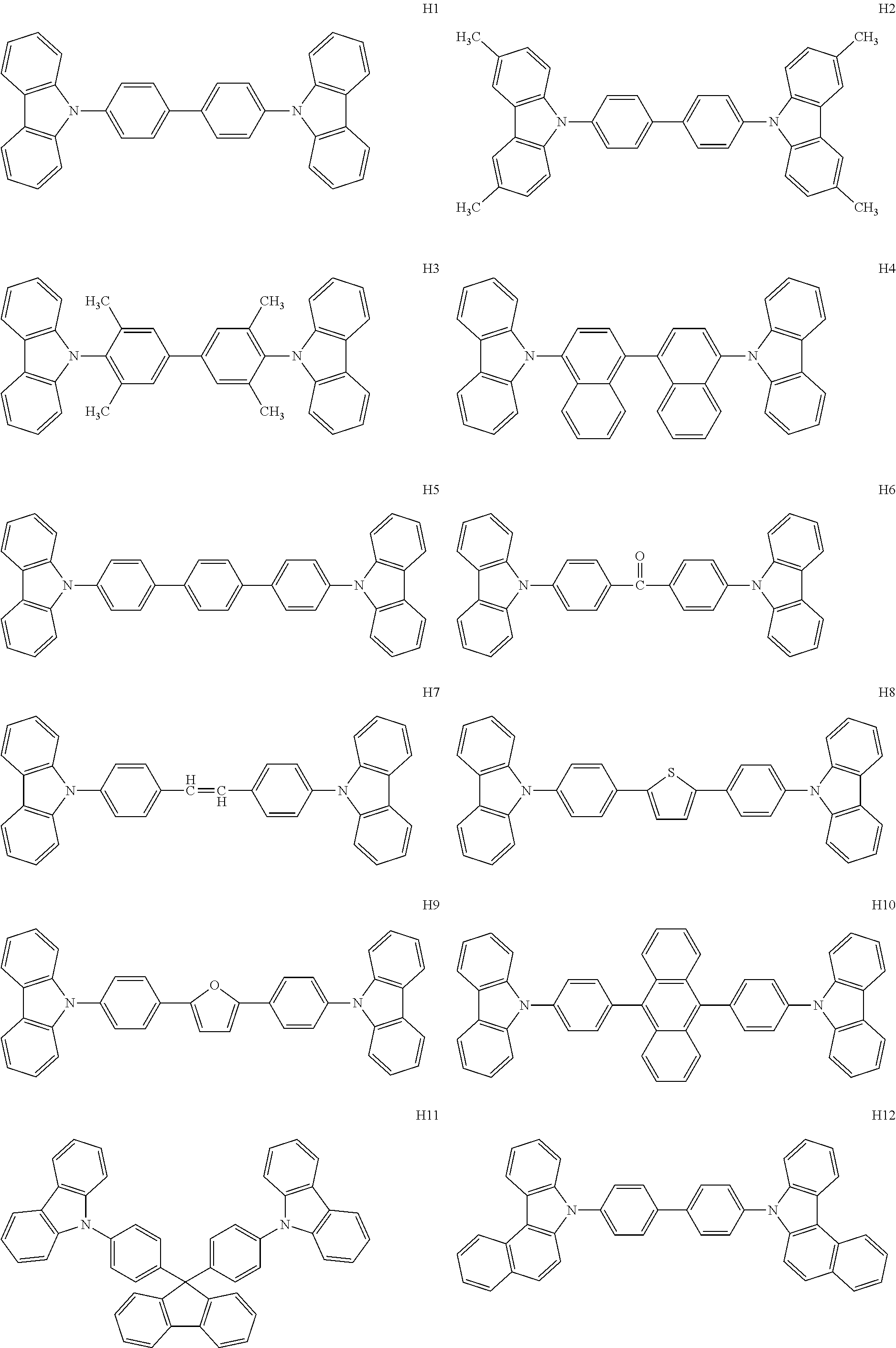

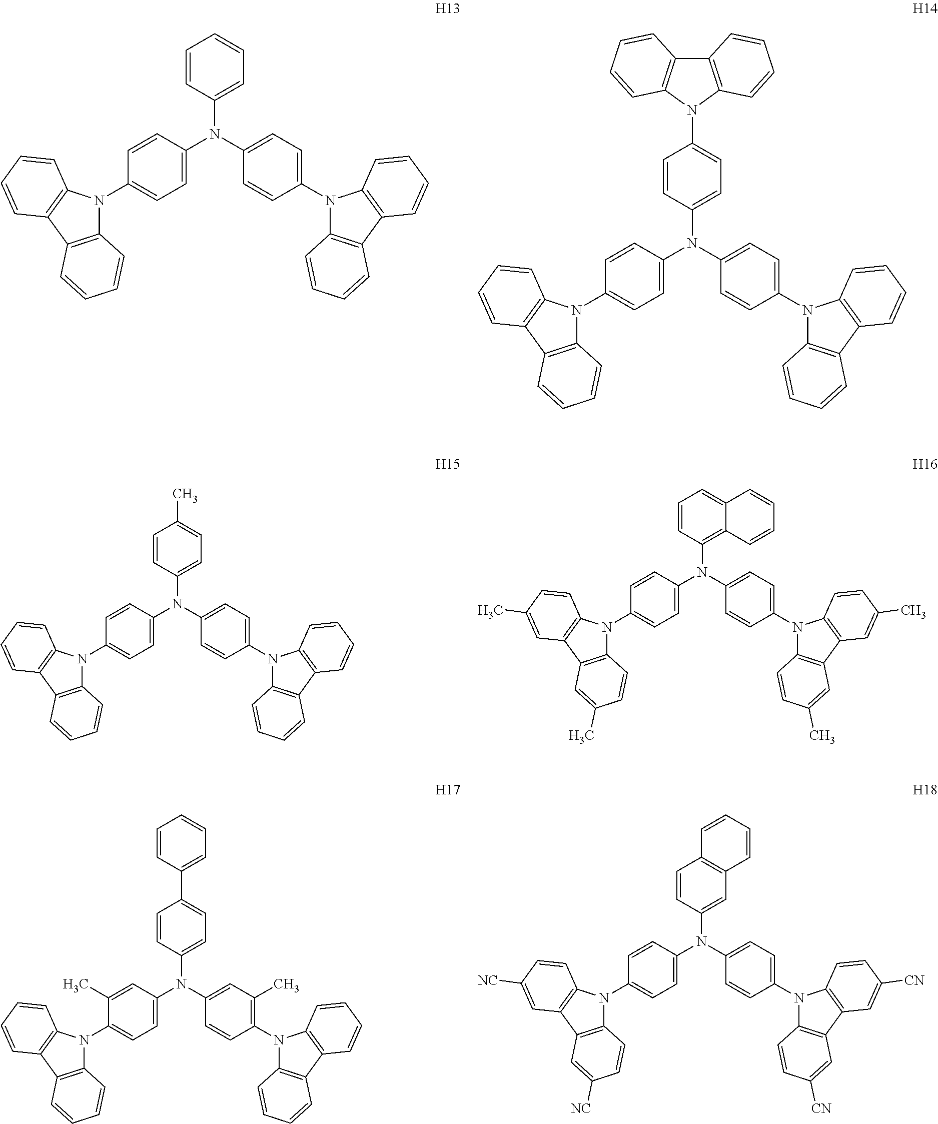

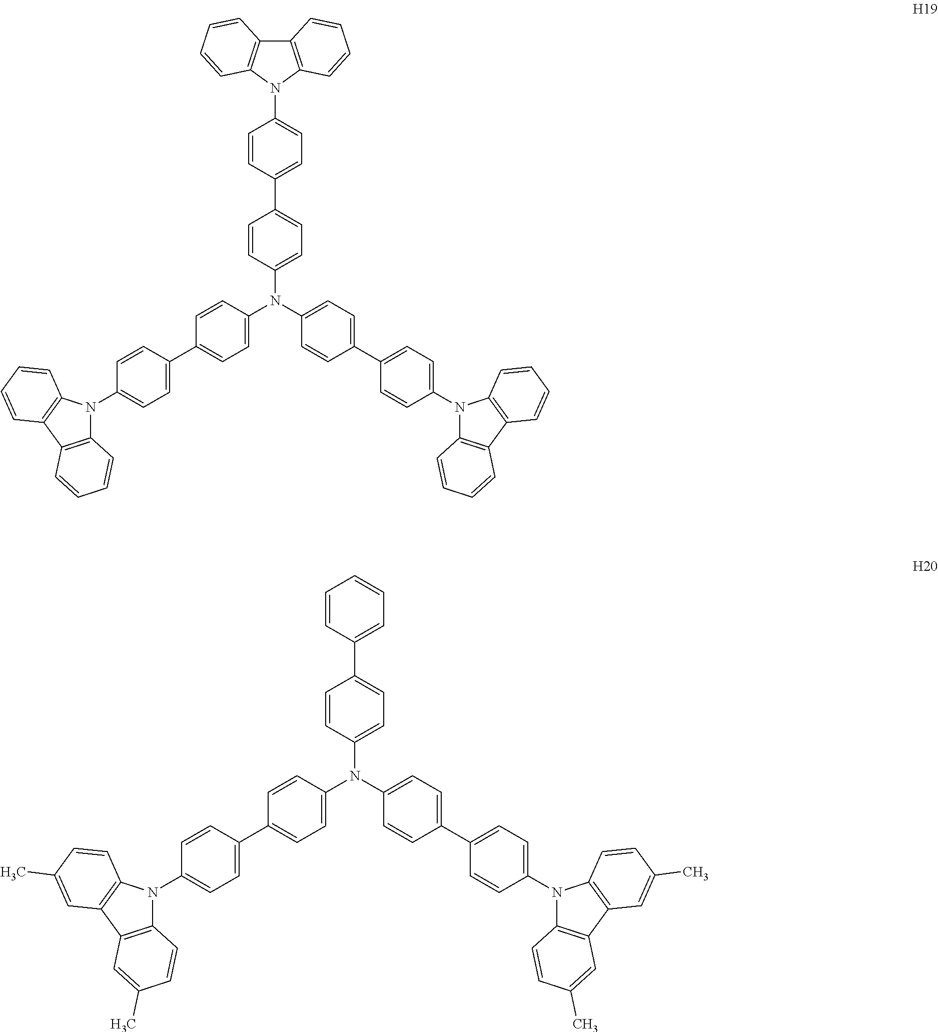

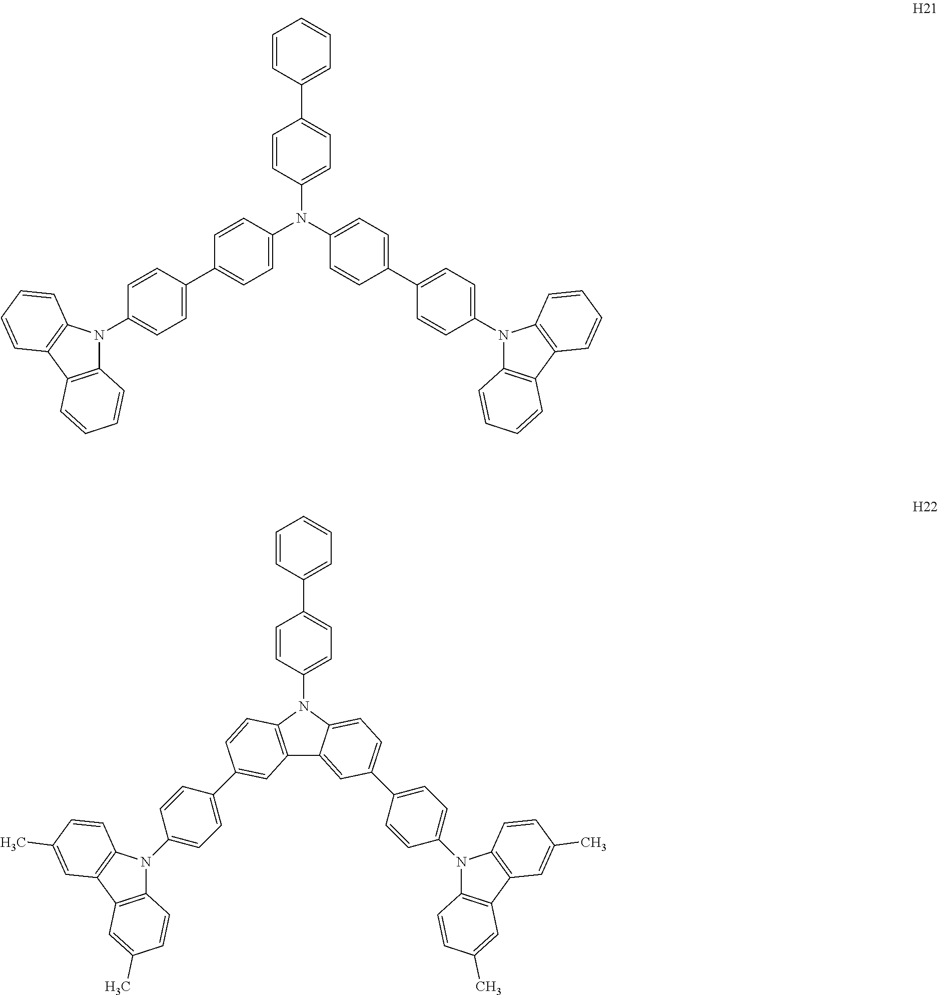

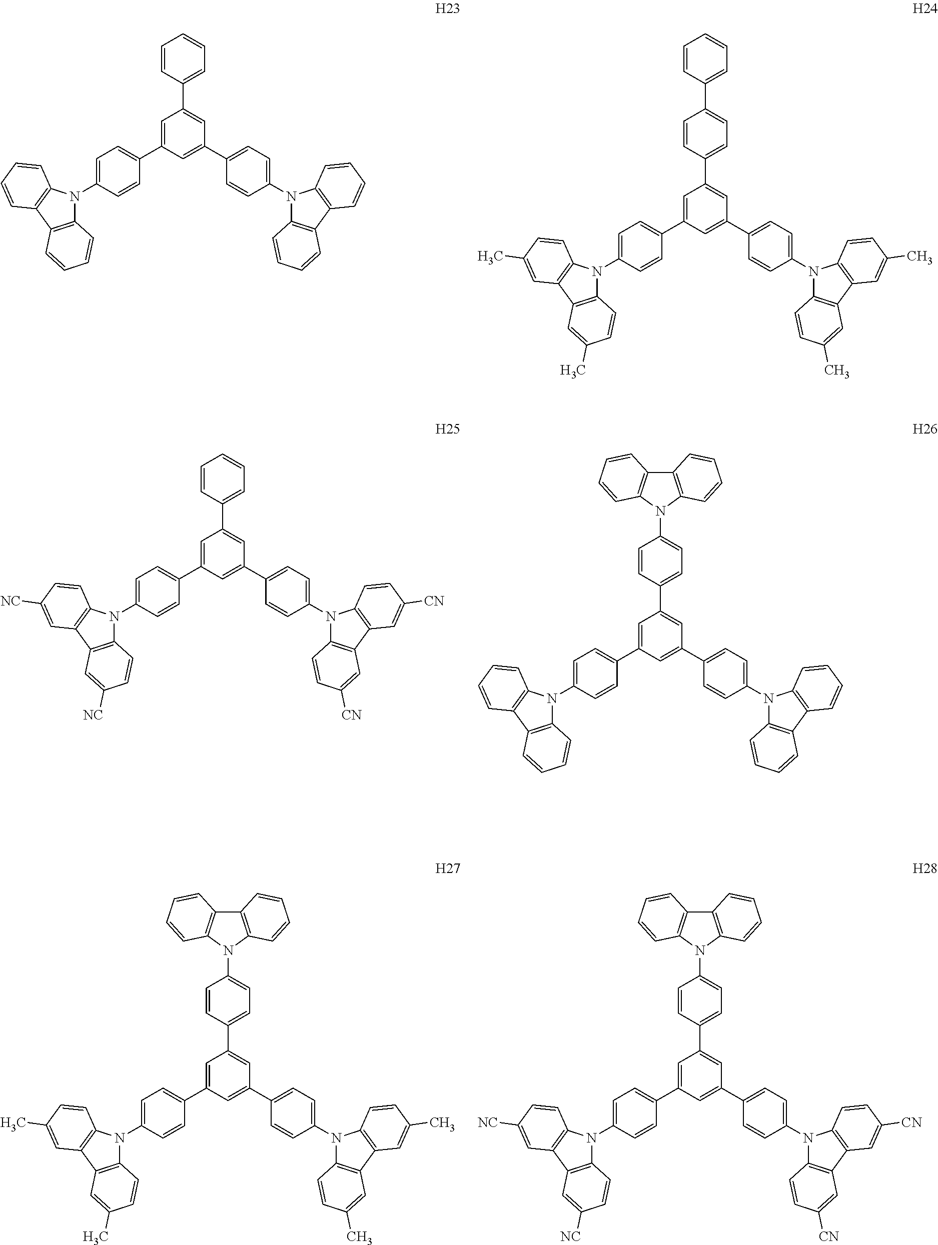

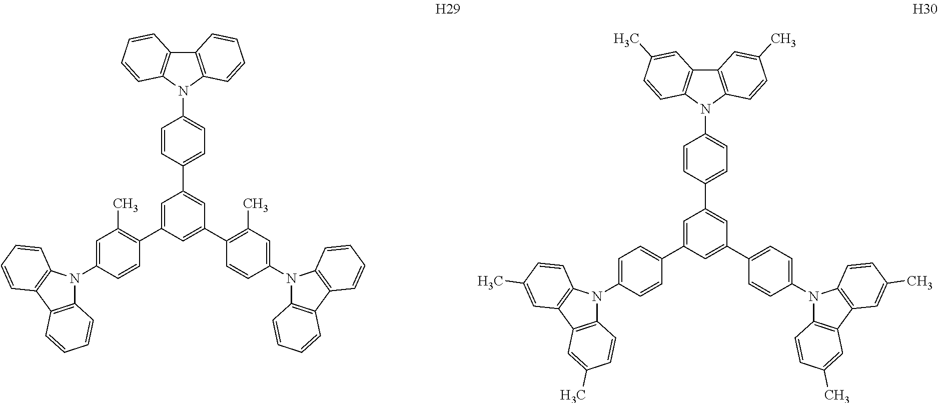

When the EML includes a host and a dopant (e.g., the iridium complex represented by Formula 1), an amount of the dopant may be about 0.01 to about 15 wt %, based on 100 wt % of the EML. In an implementation, the amount of the dopant may be about 1 to about 15 wt %, based on 100 wt % of the EML.

The thickness of the EML may be about 200 Å to about 700 Å. When the thickness of the ETL is within these ranges, excellent luminescent properties may be obtained without a substantial increase in driving voltage.

Next, the ETL may be formed on the EML by using various methods such as vacuum deposition, spin coating, or casting. When the ETL is formed by vacuum deposition or spin coating, the deposition and coating conditions may vary according to used compounds. In an implementation, the deposition and coating conditions may be almost the same as the conditions for forming the HIL. A material for forming the ETL may include a suitable electron transporting material that stably transports electrons injected from a cathode. Examples of the electron transporting materials may include a quinoline derivative such as tris(8-quinolinolate)aluminum (Alq₃), TAZ, Balq, beryllium bis(benzoquinolin-10-olate) (Bebq₂), ADN, Compound 101 below, Compound 102 below, and Bphen.

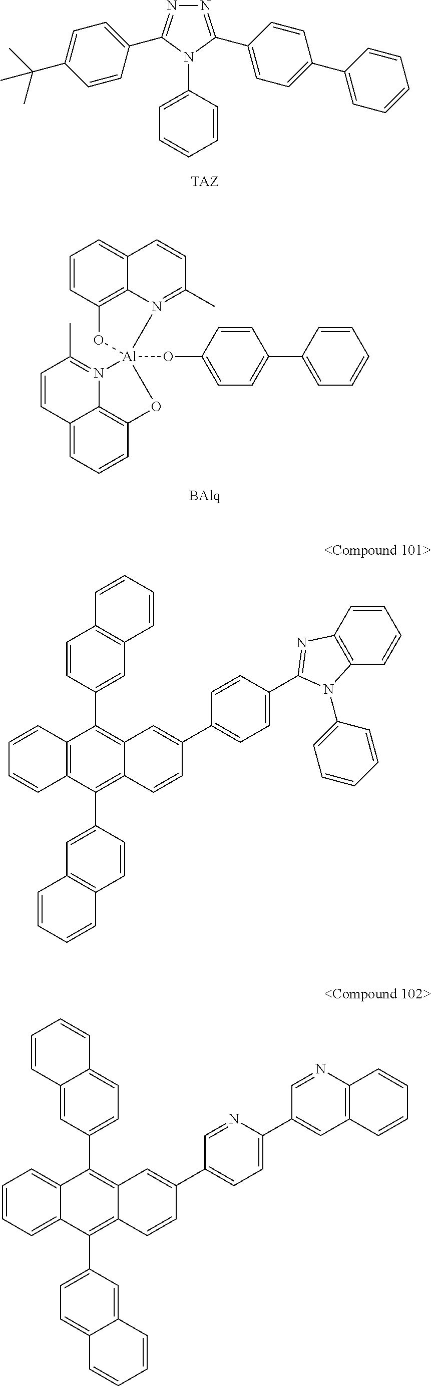

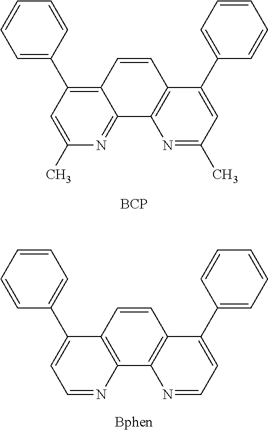

The thickness of the ETL may be in the range of about 100 Å to about 1,000 Å. In some embodiment, the thickness of the ETL may be in the range of about 150 Å to about 500 Å. When the thickness of the ETL is within these ranges, satisfactory electron transport properties may be obtained without a substantial increase in driving voltage.

The ETL may include a suitable electron transporting organic compound and a metal-containing material.

The metal-containing material may include a Li-complex. Examples of the Li-complex may include lithium quinolate (Liq) or Compound 203 below:

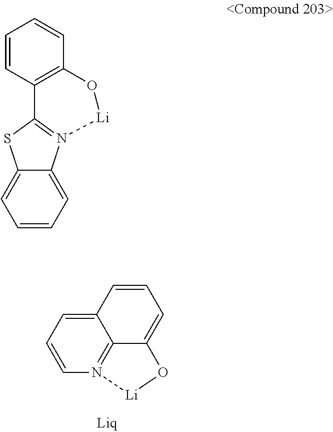

In addition, the EIL, which facilitates electron injection from a cathode, may be formed on the ETL.

The material for forming the EIL may include a suitable material for forming an EIL, e.g., LiF, NaCl, CsF, Li₂O, or BaO. The deposition conditions of the EIL may vary according a used compound. In an implementation, the conditions may be almost the same as the conditions for forming the HIL.

The thickness of the EIL may be about 1 Å to about 100 Å. In some embodiment, the thickness of the EIL may be about 3 Å to about 90 Å. When the thickness of the EIL is within these ranges, satisfactory electron injection properties may be obtained without a substantial increase in driving voltage.

The second electrode may be formed on the organic layers. The second electrode may be a cathode, which is an electron injection electrode. Here, a metal for forming the second electrode may include a metal having low work function, such as metal, an alloy, an electric conducting compound, or a mixture thereof. For example, the second electrode may be formed as a thin film by using lithium (Li), magnesium (Mg), aluminum (Al), aluminum-lithium (Al—Li), calcium (Ca), magnesium-indium (Mg—In), or magnesium-silver (Mg—Ag), thus being transparent. In order to obtain a top-emission type OLED, the second electrode may be formed as a transparent electrode by using ITO or IZO.

In addition, when the EML includes a phosphorescent dopant, a HBL may be formed between the HTL and the EML or between the E-functional layer and the EML by using various methods such as vacuum deposition, spin coating, casting, or LB deposition in order to prevent triplet excitons or holes from diffusing into the ETL. When the HBL is formed by vacuum deposition or spin coating, the deposition and coating conditions vary according to a used compound. In an implementation, the deposition and coating conditions may be almost the same as the conditions for forming the HIL. A material for forming the HBL may include a suitable hole blocking material, such as an oxadiazole derivative, a triazole derivative, or a phenanthroline derivative. For example, the material for forming the HBL may be BCP below.

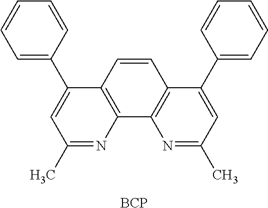 [SMILES: Cc1cc(-c2ccccc2)c2ccc3c(-c4ccccc4)cc(C)nc3c2n1 ; "BCP"]

The thickness of the HBL may be about 20 Å to about 1,000 Å, e.g., about 30 Å to about 300 Å. When the thickness of the HBL is within these ranges, satisfactory hole blocking properties may be obtained without a substantial increase in driving voltage.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Example 1

### Synthesis of Complex 1

### Synthesis of Intermediate 1-1

Intermediate 1-1 was synthesized according to Reaction Scheme 1(1) below:

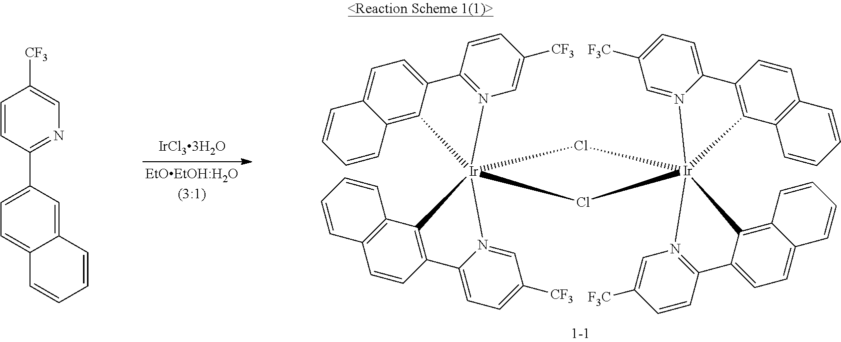

5.0 g (18.3 mmol) of 2-(naphthalen-2-yl)-5-(trifluoromethyl)pyridine was dissolved in 45 mL of 2-ethoxyethanol, 2.4 g (7.6 mmol) of iridium chloride hydrate and 15 mL of distilled water were added thereto, and the resulting solution was stirred at 130° C. for 20 hours. After the reaction was completed, the reaction solution was cooled to room temperature and filtered to obtain a precipitate. Thereafter, the precipitate was washed with methanol and dried in vacuum to obtain 4.8 g of Intermediate 1-1.

Synthesis of Complex 1

Complex 1 was synthesized according to Reaction Scheme 1(2) below:

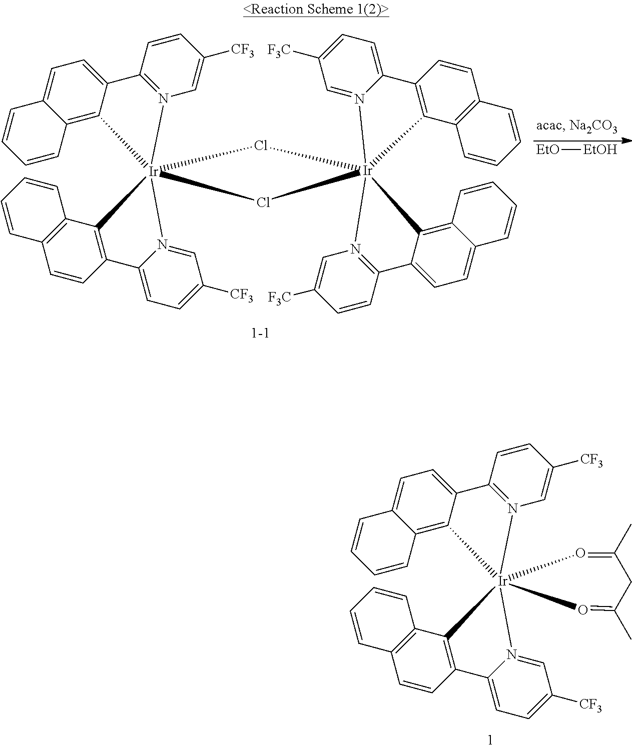

1.0 g (1.03 mmol) of Intermediate 1-1, 0.24 g (2.44 mmol) of acetyl acetonate, and 0.34 g (2.46 mmol) of Na₂CO₃ were added to 30 mL of 2-ethoxyethanol and the resulting solution was stirred at 130° C. for 12 hours. After the reaction was completed, the reaction solution was cooled to room temperature and filtered to obtain a precipitate, and the precipitate was washed with methanol. Thereafter, the precipitate was dissolved using dichloromethane, the resulting solution was filtered through a silica short pad, the filtered dichloromethane solution was boiled, and methanol was dropwise added thereto to obtain 0.70 g of a phosphorescent compound represented by Complex 1 above as a precipitate.

¹H-NMR: 8.46 (2H), 8.31 (2H), 8.14 (2H), 8.06 (4H), 7.96 (2H), 7.54 (4H), 7.36 (2H), 2.12 (6H) APCI-MS (m/z): [M+] 835

### Synthesis Example 2

### Synthesis of Complex 2

Synthesis of Complex 2

Complex 2 was synthesized according to Reaction Scheme 2 below:

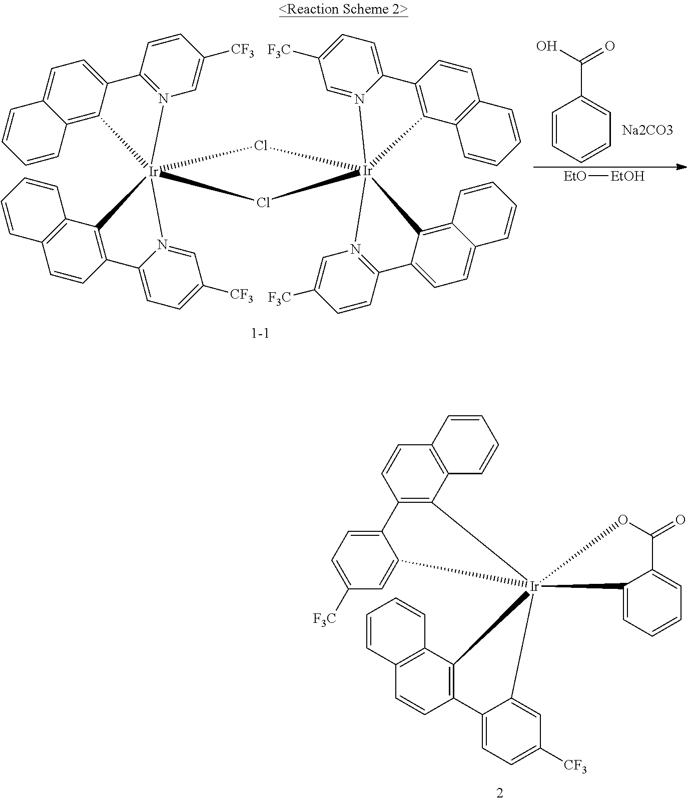

1.0 g (1.03 mmol) of Intermediate 1-1, 0.3 g (2.44 mmol) of benzoic acid, and 0.34 g (2.46 mmol) of Na₂CO₃ were added to 30 mL of 2-ethoxyethanol and the resulting solution was stirred at 130° C. for 12 hours. After the reaction was completed, the reaction solution was cooled to room temperature and filtered to obtain a precipitate, and the precipitate was washed with methanol. Thereafter, the precipitate was dissolved using dichloromethane, the resulting solution was filtered through a silica short pad, the filtered dichloromethane solution was boiled, and methanol was dropwise added thereto to obtain 0.78 g of a phosphorescent compound represented by Complex 2 above as a precipitate.

¹H-NMR: 8.44 (2H), 8.30 (2H), 8.21 (1H), 8.15 (2H), 8.08 (4H), 7.96 (2H), 7.79 (1H), 7.66 (2H), 7.54 (4H), 7.36 (2H), 2.12 (6H) APCI-MS (m/z): [M+] 857

### Synthesis Example 3

### Synthesis of Complex 3

Synthesis of Complex 3

Complex 3 was synthesized according to Reaction Scheme 3 below:

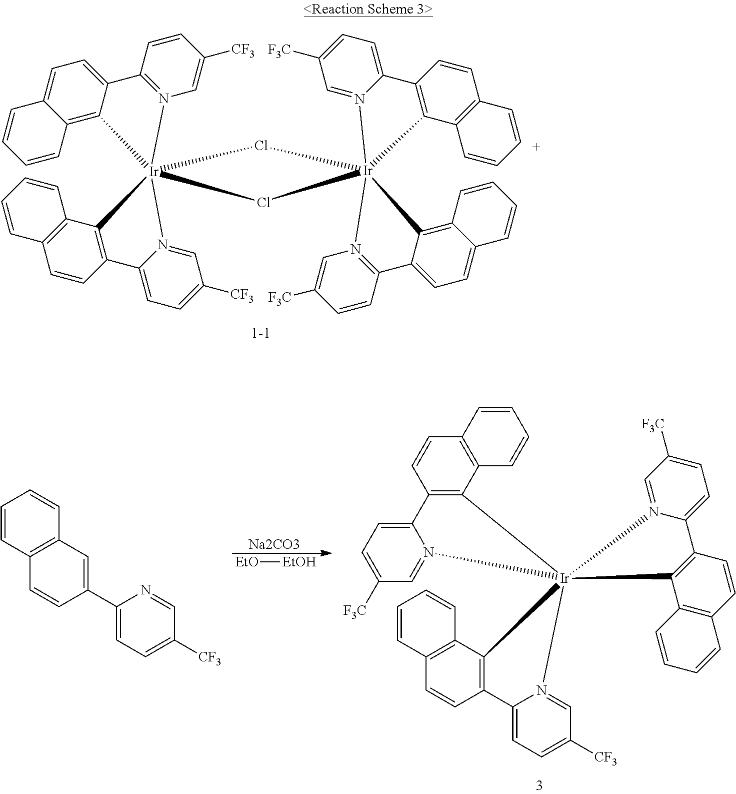

1.0 g (1.03 mmol) of Intermediate 1-1, 0.67 g (2.44 mmol) of 2-(naphthalen-2-yl)-5-(trifluoromethyl)pyridine, and 0.34 g (2.46 mmol) of Na₂CO₃ were added to 30 mL of 2-ethoxyethanol and the resulting solution was stirred at 130° C. for 12 hours. After the reaction was completed, the reaction solution was cooled to room temperature and filtered to obtain a precipitate, and the precipitate was washed with methanol. Thereafter, the precipitate was dissolved using dichloromethane, the resulting solution was filtered through a silica short pad, the filtered dichloromethane solution was boiled, and methanol was dropwise added thereto to obtain 0.70 g of a phosphorescent compound represented by Complex 3 above as a precipitate.

¹H-NMR: 8.44 (3H), 8.31 (3H), 8.14 (3H), 8.06 (3H), 7.96 (3H), 7.54 (6H), 7.36 (3H), APCI-MS (m/z): [M+] 1009

### Example 1

As an anode, a 15 Ω/cm² (1,200 Å) Corning ITO glass substrate was cut to a size of 50 mm×50 mm×0.7 mm, washed with ultrasonic waves in isopropyl alcohol and pure water for 5 minutes each, and then cleaned with UV and ozone for 30 minutes. The ITO glass substrate was mounted on a vacuum depositor.

2-TNATA was vacuum deposited on the ITO glass substrate to form a HIL having a thickness of 600 Å and Compound 301 was vacuum deposited on the HIL to form a HTL having a thickness of 300 Å.

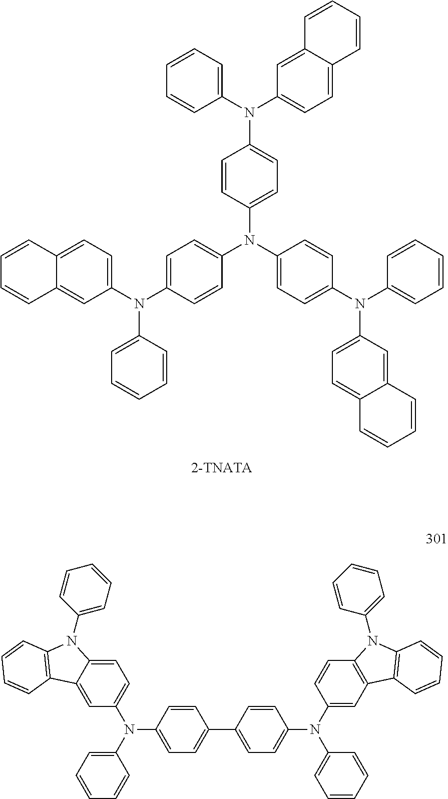 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

Next, Compound 401 (as a phosphorescent host) and the iridium Complex 1 were co-deposited on the HTL in a weight ratio of 98:2 to form an EML having a thickness of 400 Å. Subsequently, Compound 501 was deposited on the EML to form an ETL having a thickness of 300 Å, LiF was deposited on the ETL to form an EIL having a thickness of 10 Å, and Al was deposited on the EIL to form a LiF/Al electrode (cathode) having a thickness of 3,000 Å, thereby completing the manufacture of an OLED.

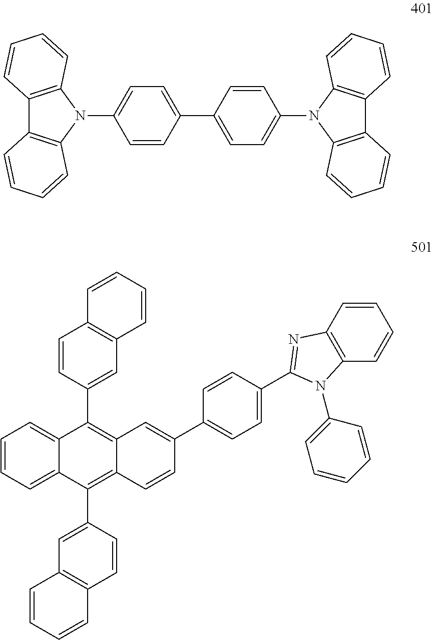 [SMILES: c1ccc2c(c1)c1ccccc1n2-c1ccc(-c2ccc(-n3c4ccccc4c4ccccc43)cc2)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

### Example 2

An organic light-emitting device was manufactured in the same manner as in Example 1, except that Complex 2 was used instead of Complex 1 in formation of the EML.

### Example 3

An organic light-emitting device was manufactured in the same manner as in Example 1, except that Complex 3 was used instead of Complex 1 in formation of the EML.

### Example 4

An organic light-emitting device was manufactured in the same manner as in Example 1, except that Compound 311 was used instead of Compound 301 in formation of the HTL.

### Example 5

An organic light-emitting device was manufactured in the same manner as in Example 1, except that Compound 314 was used instead of Compound 301 in formation of the HTL.

### Comparative Example 1

An organic light-emitting device was manufactured in the same manner as in Example 1, except that Compound 501, below, was used as a light-emitting material instead of Complex 1 in formation of the EML.

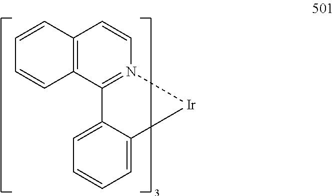

### Comparative Example 2

An organic light-emitting device was manufactured in the same manner as in Example 1, except that Compound 502, below, was used as a light-emitting material instead of Complex 1 in formation of the EML.

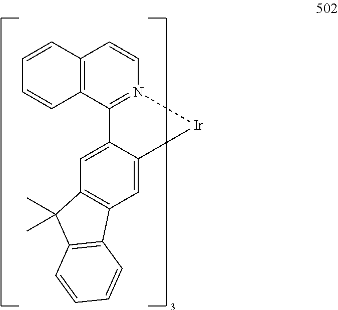

### Comparative Example 3

An organic light-emitting device was manufactured in the same manner as in Example 1, except that Compound 503, below, was used instead of Compound 301 in formation of the HTL.

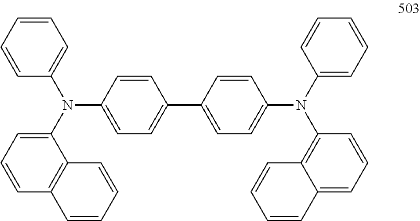 [SMILES: c1ccc(N(c2ccc(-c3ccc(N(c4ccccc4)c4cccc5ccccc45)cc3)cc2)c2cccc3ccccc23)cc1]

Efficiencies and color purities of the organic light-emitting devices according to Examples 1 to 5 and Comparative Examples 1 to 3 were evaluated using PR650 Spectroscan Source Measurement Unit (manufactured by PhotoResearch). Results are shown in Table 1, below.

TABLE 1

| | EML | Driving voltage | Efficiency (cd/A) |
|---|---|---|---|
| | HTL | @10 mA/cm2 | @10 mA/cm² |
| Example 1 | Complex 1 and | 4.9 | 29.5 |
| | Compound 301 | | |
| Example 2 | Complex 2 and | 5.1 | 27.3 |
| | Compound 301 | | |
| Example 3 | Complex 3 and | 5.3 | 26.4 |
| | Compound 301 | | |
| Example 4 | Complex 1 and | 5.2 | 26.7 |
| | Compound 311 | | |
| Example 5 | Complex 1 and | 5.4 | 25.2 |
| | Compound 314 | | |
| Comparative | Compounds 501 | 6.6 | 18.2 |
| Example 1 | and 301 | | |
| Comparative | Compounds 502 | 7.3 | 14.8 |
| Example 2 | and 301 | | |
| Comparative | Complex 1 and | 7.5 | 13.2 |
| Example 3 | Compound 503 | | |

From the results shown in Table 1, it may be seen that the organic light-emitting devices according to Examples 1 to 5 exhibited a lower driving voltage and enhanced efficiency characteristics, when compared to the organic light-emitting devices according to Comparative Examples 1 to 3.

By way of summation and review, an OLED may have a structure including, e.g., a substrate, an anode, a hole transport layer (HTL), an emission layer (EML), an electron transport layer (ETL), and a cathode which are sequentially stacked on the substrate. In this regard, the HTL, the EML, and the ETL may be organic layers formed of organic compounds.

An operating principle of an OLED having the above-described structure may be as follows. When a voltage is applied between the anode and the cathode, holes injected from the anode may move to the EML via the HTL, and electrons injected from the cathode may move to the EML via the ETL. The holes and electrons may recombine in the EML to generate excitons. When the excitons drop from an excited state to a ground state, light may be emitted.

The embodiments may provide an organic light emitting device having high efficiency, low voltage, high brightness, and long lifespan.

As described above, according to the one or more of the above embodiments, an organic light-emitting device may have high efficiency, low voltage, high luminance, and long lifespan.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode; and
an organic layer between the first electrode and the second electrode,
wherein the organic layer includes an emission layer and any one of a hole injection layer, a hole transport layer, or a functional layer having hole injection and hole transport abilities,
wherein the emission layer includes an organic metal complex represented by Formula 1 below, and
wherein the hole injection layer, the hole transport layer, or the functional layer having hole injection and hole transport abilities includes a compound represented by Formula 2 or 3 below, 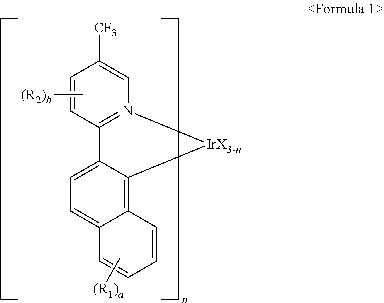
wherein R₁ and R₂ are each independently selected from hydrogen, deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, and a substituted or unsubstituted C₂-C₆₀ heteroaryl group;
X is a monovalent anion bidentate ligand;
a is an integer of 1 to 3;
b is an integer of 1 to 6, wherein, when b is 2 or more, a plurality of R₂ groups are selectively linked to each other to form a ring;
n is 2 or 3; 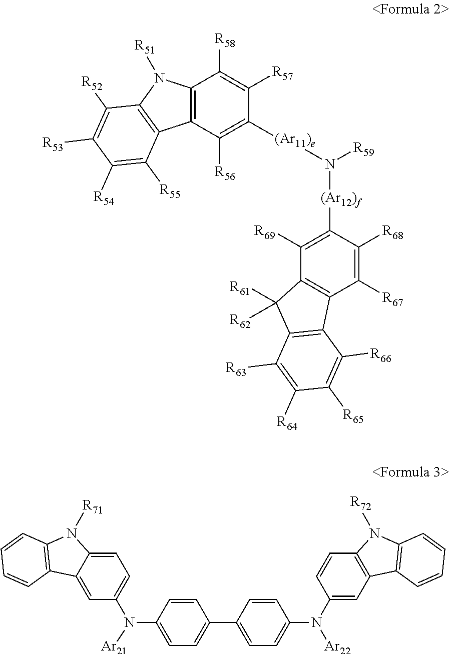
wherein Ar₁₁ and Ar₁₂ are each independently a substituted or unsubstituted C₆-C₆₀ arylene group;
Ar₂₁ and Ar₂₂ are each independently a substituted or unsubstituted C₆-C₆₀ aryl group;
e and f are each independently an integer of 0 to 5;
R₅₁ through R₅₈, R₆₁ through R₆₉, R₇₁, and R₇₂ are each independently hydrogen, deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group; and
R₅₉ is a phenyl group; a naphthyl group; an anthryl group; a biphenyl group; a pyridyl group; or a phenyl group, a naphthyl group, an anthryl group, a biphenyl group, or a pyridyl group substituted with at least one of deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

2. The organic light-emitting device as claimed in claim 1, wherein R₁ and R₂ are each independently one of a C₆-C₁₄ aryl group and a C₂-C₁₄ heteroaryl group; or a C₆-C₁₄ aryl group and a C₂-C₁₄ heteroaryl group that are substituted with at least one of deuterium, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, and a C₁-C₂₀ alkoxy group, a C₆-C₁₄ aryl group, and a C₂-C₁₄ heteroaryl group.

3. The organic light-emitting device as claimed in claim 1, wherein R₁ and R₂ are each independently one of a phenyl group; a biphenyl group; a naphthyl group; an anthryl group; pyrenyl group; a phenanthrenyl group; a fluorenyl group; a pyridinyl group; a pyrazinyl group; a pyrimidinyl group; a triazinyl group; a quinolinyl group; an isoquinolinyl group; a quinoxalinyl group; a phenanthrolinyl group; a carbazolyl group; or a phenyl group, a biphenyl group, a naphthyl group, an anthryl group, a pyrenyl group, a phenanthrenyl group, a fluorenyl group, a pyridinyl group, a bipyridinyl group, a terpyridinyl group, a pyrazinyl group, a pyrimidinyl group, a triazinyl group, a quinolinyl group, an isoquinolinyl group, a quinoxalinyl group, a phenanthrolinyl group, and a carbazolyl group that are substituted with at least one of deuterium, F, Cl, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazolyl group.

4. The organic light-emitting device as claimed in claim 1, wherein R₁ and R₂ are each independently hydrogen, deuterium, —CF₃, or a group represented by Formula 2a below: 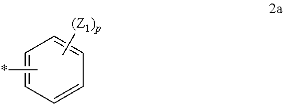
wherein Z₁ is a hydrogen atom, deuterium, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, an amino group substituted with a C₆-C₂₀ aryl group or a C₂-C₂₀ heteroaryl group, a halogen group, a cyano group, a nitro group, a hydroxyl group, or a carboxyl group;
p is an integer of 1 to 5; and
* denotes a binding site.

5. The organic light-emitting device as claimed in claim 1, wherein the complex represented by Formula 1 is represented by Formula 1-1 below: 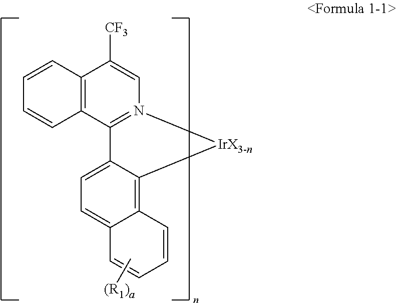
wherein R₁, a, X, and n are the same as described with respect to Formula 1.

6. The organic light-emitting device as claimed in claim 1, wherein X is aetylacetonate, hexafluoroacetonate, tetramethylheptadionate, dibenzoylmethane, picolinate, salicylanilide, 8-hydroxyquinolate, or 1,5-dimethyl-3-pyrazole carboxylate.

7. The organic light-emitting device as claimed in claim 1, wherein X is represented by Formula 3a or 3b below: 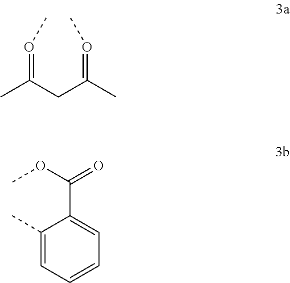
wherein dotted lines denote binding locations with Ir.

8. The organic light-emitting device as claimed in claim 1, wherein the organic metal complex represented by Formula 1 is any one of the following compounds:

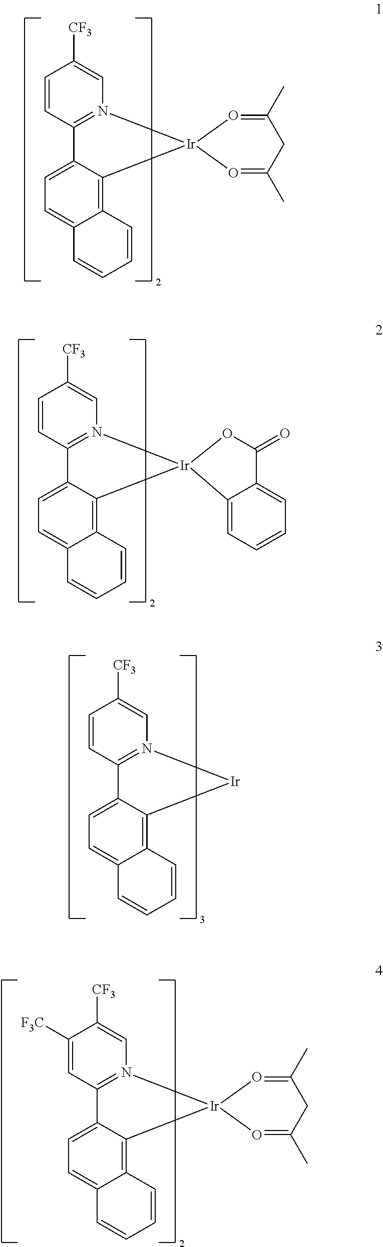

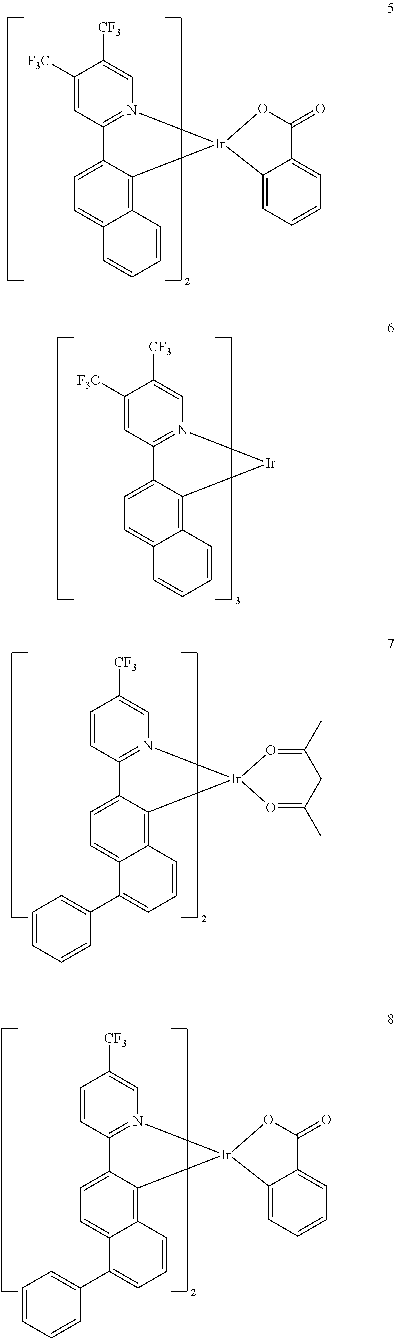

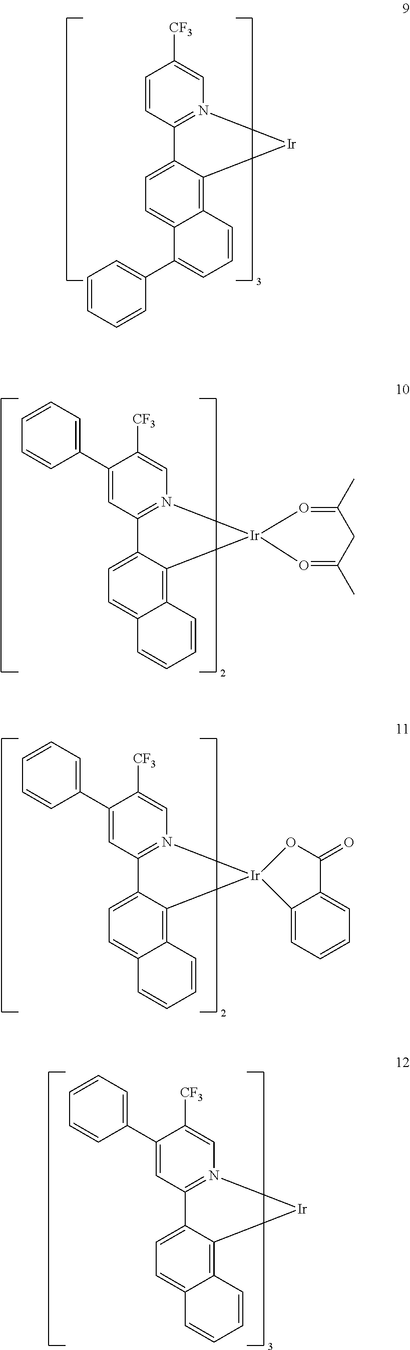

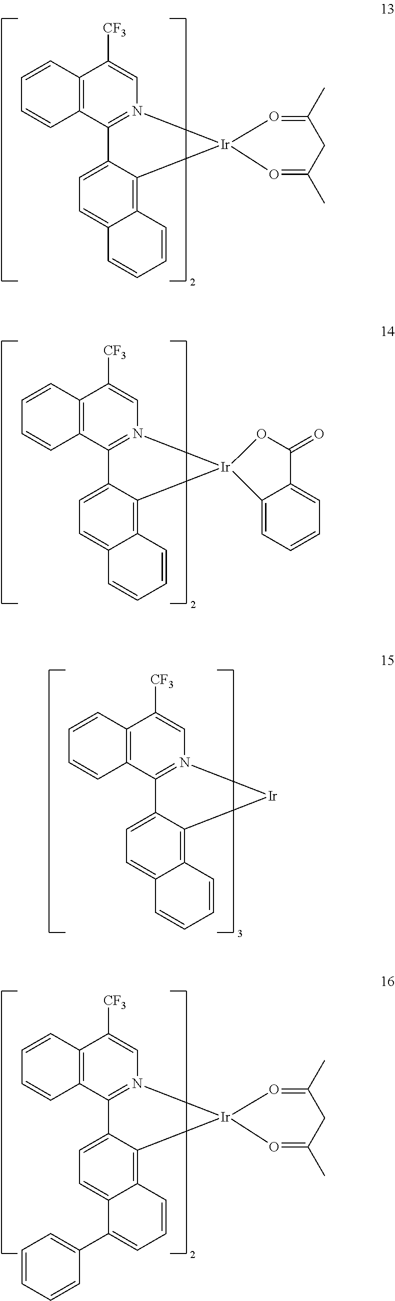

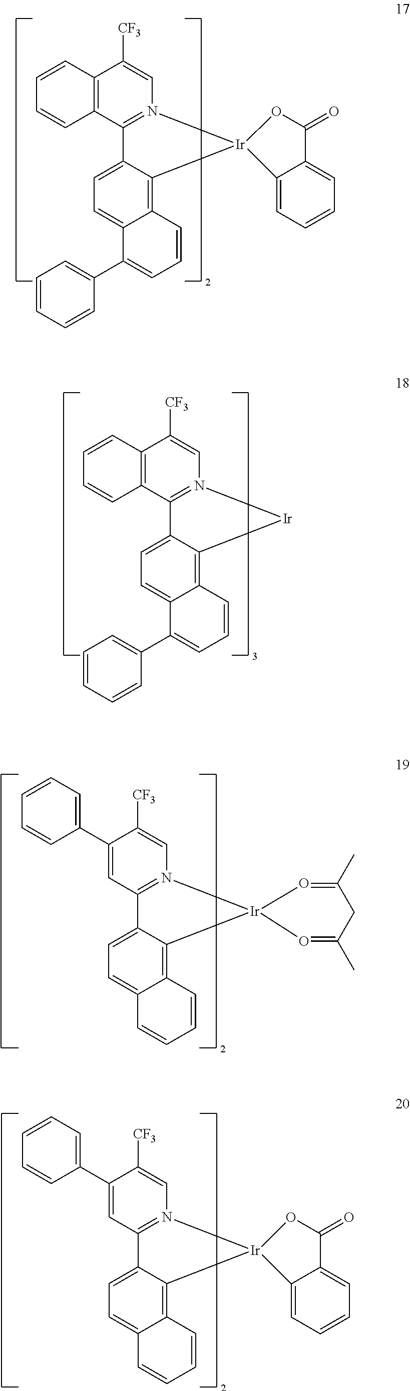

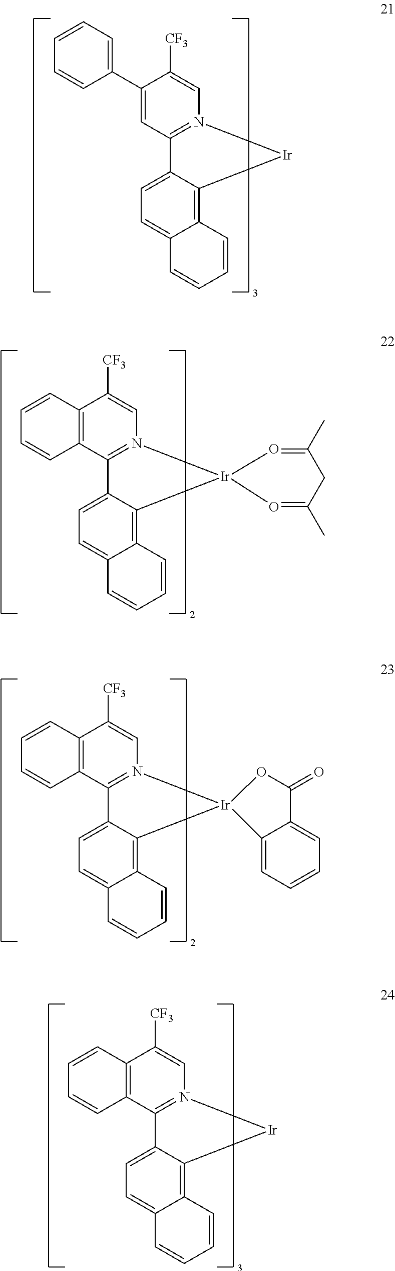

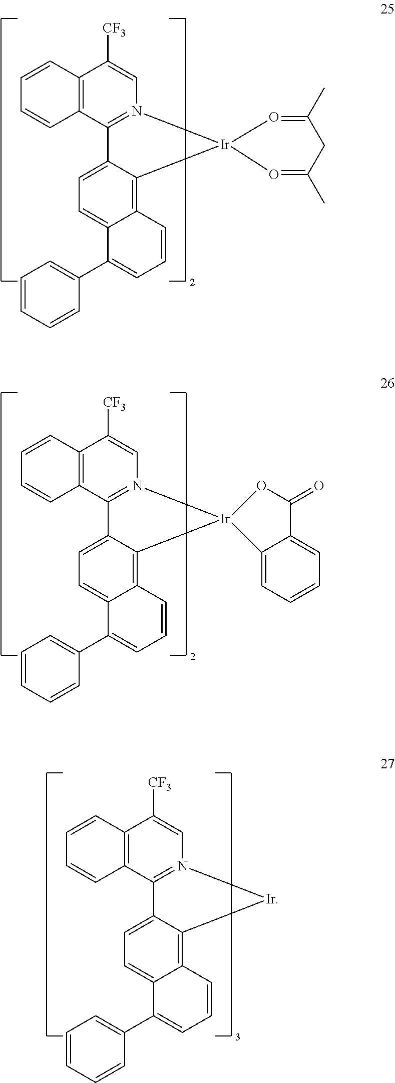

9. The organic light-emitting device as claimed in claim 1, wherein the compound represented by Formula 2 is represented by Formula 4 below: 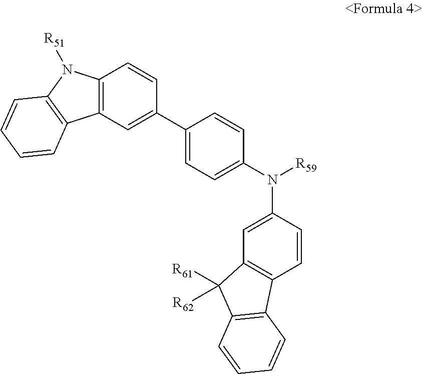
wherein R₅₁, R₅₉, R₆₂, and R₆₁ are the same as defined with respect to Formula 2.

10. The organic light-emitting device as claimed in claim 1, wherein the compound represented by Formula 2 is any one of the following compounds:

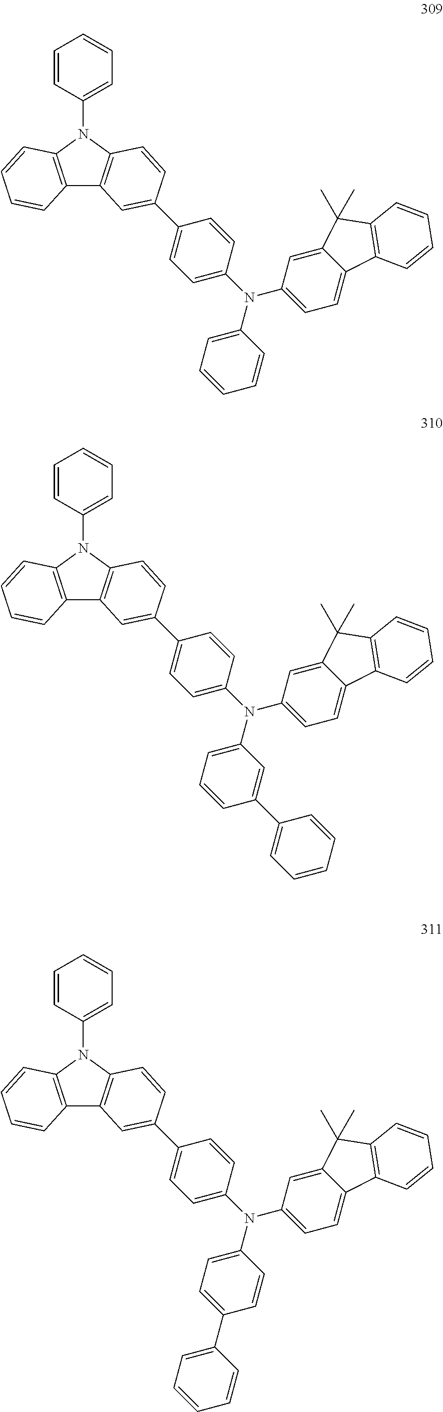 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

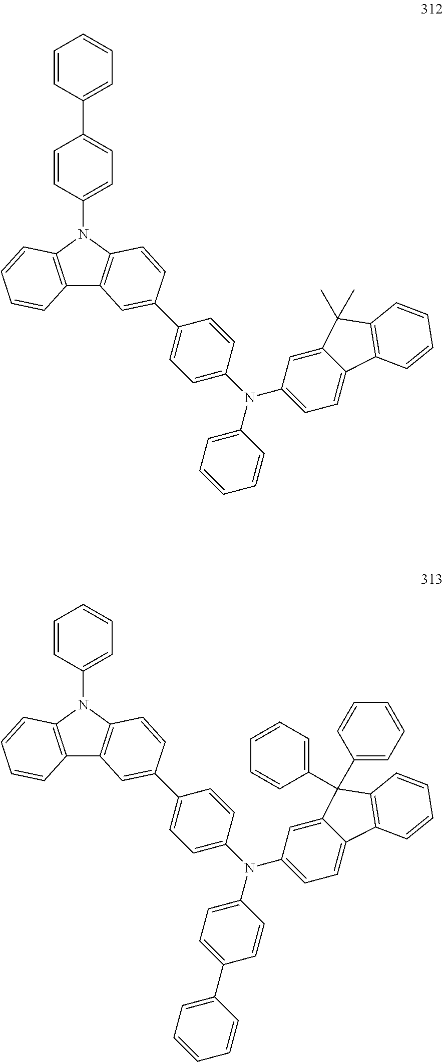 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

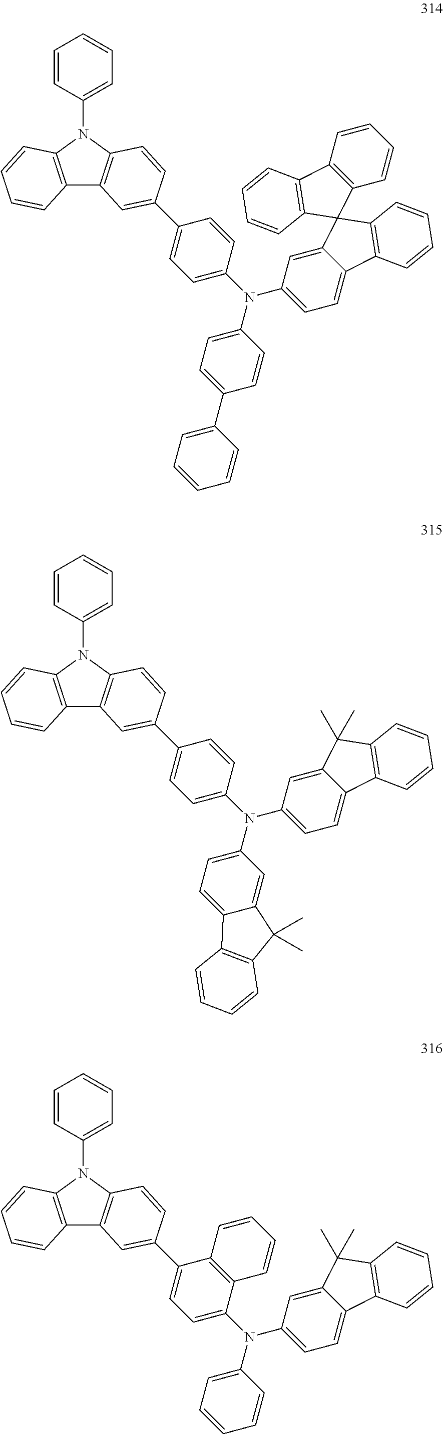 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

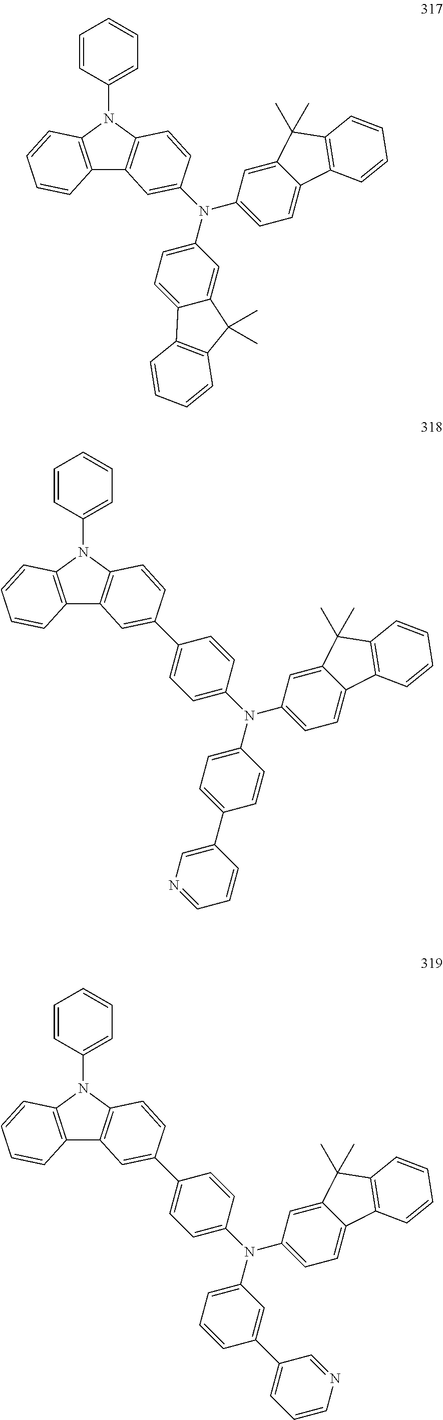 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

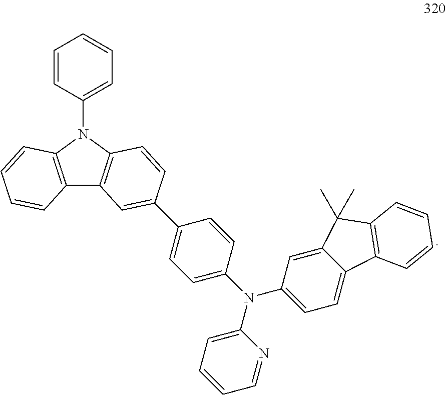 [SMILES: CC1(C)c2ccccc2-c2ccc(N(c3ccc(-c4ccc5c(c4)c4ccccc4n5-c4ccccc4)cc3)c3ccccn3)cc21]

11. The organic light-emitting device as claimed in claim 1, wherein the compound represented by Formula 3 is any one of the following compounds:

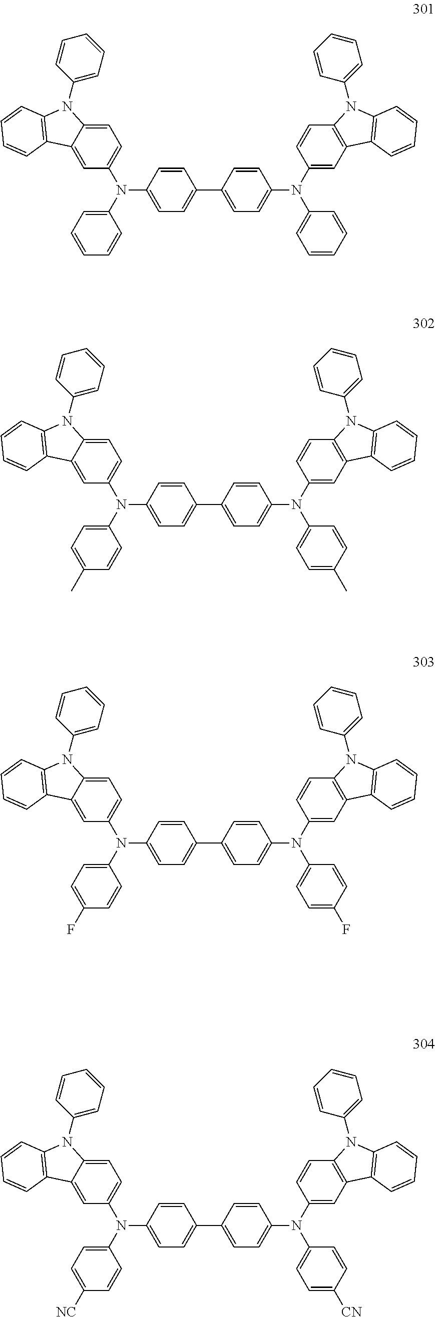 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

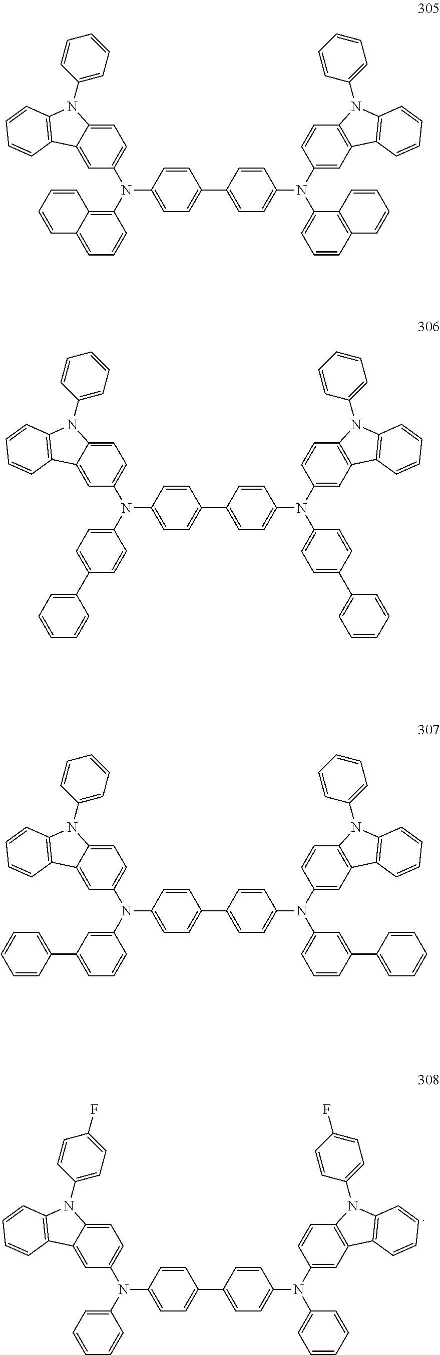 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

12. The organic light-emitting device as claimed in claim 1, wherein the emission layer is a red phosphorescent emission layer, and the organic metal complex is a phosphorescent dopant.

13. The organic light-emitting device as claimed in claim 1, wherein:
the organic layer includes the emission layer and any one of the hole injection layer, the hole transport layer, or the functional layer having hole injection and hole transport abilities, and further includes any one of an electron injection layer, an electron transport layer, or a functional layer having electron injection and electron transport abilities, and
the emission layer further includes an anthracene-based compound, an arylamine-based compound, or a styryl-based compound.

14. The organic light-emitting device as claimed in claim 1, wherein the hole injection layer, the hole transport layer, or the functional layer having hole injection and hole transport abilities further include a charge-generating material.

15. The organic light-emitting device as claimed in claim 14, wherein the charge-generating material is a p-dopant.

16. The organic light-emitting device as claimed in claim 15, wherein the p-dopant is a quinone derivative, a metal oxide, or a cyano-containing compound.

17. The organic light-emitting device as claimed in claim 1, wherein:
the organic layer includes the emission layer and further includes any one of an electron injection layer, an electron transport layer, or a functional layer having electron injection and electron transport abilities,
wherein the electron injection layer, the electron transport layer, or the functional layer having electron injection and electron transport abilities includes an electron transporting organic compound and a metal-containing material.

18. The organic light-emitting device as claimed in claim 17, wherein the metal-containing material is lithium quinolate (LiQ) or Compound 203 below:

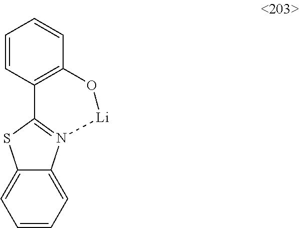

19. The organic light-emitting device as claimed in claim 1, wherein the organic layer is formed through a wet process using any of the organic metal complex represented by Formula 1, the compound represented by Formula 2, or the compound represented by Formula 3.

20. A flat panel display device comprising the organic light-emitting device as claimed in claim 1, wherein the first electrode of the organic light-emitting diode is electrically connected to a source electrode or a drain electrode of a thin film transistor.
